(19) United States
(12) Patent Application Publication
(10) Pub. No.: US 2024/0423071 A1
(43) Pub. Date: Dec. 19, 2024

(54) DISPLAY DEVICE AND ELECTRONIC APPARATUS

(71) Applicant: SONY SEMICONDUCTOR SOLUTIONS CORPORATION, KANAGAWA (JP)

(72) Inventor: KENTA HIRAGA, KANAGAWA (JP)

(21) Appl. No.: 18/701,385

(22) PCT Filed: Oct. 17, 2022
(86) PCT No.: PCT/JP2022/038605

§ 371 Date: Apr. 15, 2024

(30) Foreign Application Priority Data
Oct. 22, 2021 (JP) 2021-173242

(51) Int. Cl. H10K 59/80; H10K 59/38

(52) U.S. Cl. CPC H10K 59/879; H10K 59/38; H10K 59/8791

(57) ABSTRACT

Provided is a display device capable of improving luminance and light extraction efficiency in the front direction.

The display device includes a substrate, a plurality of light emitting elements provided on the substrate, a color filter that is provided above the plurality of light emitting elements and contains a plurality of filter parts, and a wall part surrounding the filter parts. The filter part has a concave surface on a display surface side.

### TECHNICAL FIELD

The present disclosure relates to a display device and an electronic apparatus including the display device.

### BACKGROUND ART

In recent years, an organic light emitting diode (OLED) display device (hereinafter, simply referred to as a “display device”) has been widely used. An on chip lens (OCL) is known as a technology having as its purpose to improve luminance and light extraction efficiency in the front direction of a display device.

However, in a display device including an OCL, light leaks to an adjacent lens, light cannot be effectively used, and luminance and light extraction efficiency in the front direction may not be improved. For a purpose of solving the above-described problem, Patent Document 1 discloses a display device sequentially including a first microlens, a color filter, and a second microlens on a plurality of light emitting units.

### CITATION LIST

### Patent Document

Patent Document 1: WO 2020/08022 A

### SUMMARY OF THE INVENTION

### Problems to be Solved by the Invention

As described above, it has been desired in recent years to improve luminance and light extraction efficiency in the front direction of a display device.

An object of the present disclosure is to provide a display device capable of improving luminance and light extraction efficiency in the front direction and an electronic apparatus including the display device.

### Solutions to Problems

For solving the above-described problem, the present disclosure is
a display device including:
a substrate;
a plurality of light emitting elements provided on the substrate;
a color filter that is provided above the plurality of light emitting elements and contains a plurality of filter parts; and
a wall part surrounding the filter parts, in which
the filter part has a concave surface on a display surface side.

### BRIEF DESCRIPTION OF DRAWINGS

FIG. 1 is a schematic view illustrating an example of an overall configuration of a display device according to one embodiment.

FIG. 2 is a cross-sectional view illustrating an example of a configuration of a display device according to one embodiment.

FIG. 3A, FIG. 3B, and FIG. 3C are each a process diagram for explaining an example of a method for manufacturing a display device according to one embodiment.

FIG. 4A, FIG. 4B, and FIG. 4C are each a process diagram for explaining an example of a method for manufacturing a display device according to one embodiment.

FIG. 5 is a process diagram for explaining an example of a method for manufacturing a display device according to one embodiment.

FIG. 6 is a cross-sectional view illustrating a configuration of a display device according to a comparative example.

FIG. 7 is a cross-sectional view illustrating a configuration of a display device according to a comparative example.

FIG. 8A, FIG. 8B, and FIG. 8C are each a process diagram for explaining a method for manufacturing a display device according to a comparative example.

FIG. 9A and FIG. 9B are each a process diagram for explaining a method for manufacturing a display device according to a comparative example.

FIG. 10 is a cross-sectional view illustrating an example of a configuration of a display device according to Modification Example 1.

FIG. 11 is a cross-sectional view illustrating an example of a configuration of a display device according to Modification Example 2.

FIG. 12 is a cross-sectional view illustrating an example of a configuration of a display device according to Modification Example 3.

FIG. 13 is a cross-sectional view illustrating an example of a configuration of a display device according to Modification Example 3.

FIG. 14 is a cross-sectional view illustrating an example of a configuration of a display device according to Modification Example 4.

FIG. 15 is a cross-sectional view illustrating an example of a configuration of a display device according to Modification Example 4.

FIG. 16 is a cross-sectional view illustrating an example of a configuration of a display device according to Modification Example 4.

FIG. 17 is a cross-sectional view illustrating an example of a configuration of a display device according to Modification Example 5.

FIG. 18 is a cross-sectional view illustrating an example of a configuration of a display device according to Modification Example 5.

FIG. 19 is a cross-sectional view illustrating an example of a configuration of a display device according to Modification Example 5.

FIG. 20 is a cross-sectional view illustrating an example of a configuration of a display device according to Modification Example 6.

FIG. 21 is a cross-sectional view illustrating an example of a configuration of a display device according to Modification Example 7.

FIG. 22 is a cross-sectional view illustrating an example of a configuration of a display device according to Modification Example 7.

FIG. 23 is a cross-sectional view illustrating an example of a configuration of a display device according to Modification Example 8.

FIG. 24 is a cross-sectional view illustrating an example of a configuration of a display device according to Modification Example 9.

FIG. 25 is a cross-sectional view illustrating an example of a configuration of a display device according to Modification Example 10.

FIG. 26 is a cross-sectional view illustrating an example of a configuration of a display device according to Modification Example 10.

FIG. 27A and FIG. 27B are each a plan view illustrating an example of a configuration of a display device according to Modification Example 11.

FIG. 28A is a plan view illustrating an example of a configuration of a display device according to Modification Example 12. FIG. 28B is a plan view illustrating an example of a configuration of a display device according to Modification Example 13.

FIG. 29 is a plan view illustrating an example of a schematic configuration of a module.

FIG. 30A is a front view illustrating an example of an external appearance of a digital still camera. FIG. 30B is a rear view illustrating an example of an external appearance of a digital still camera.

FIG. 31 is a perspective view illustrating an example of an external appearance of a head-mounted display.

FIG. 32 is a perspective view illustrating an example of an external appearance of a television device.

### MODE FOR CARRYING OUT THE INVENTION

Embodiments of the present disclosure will be described in the following order. Note that the same or corresponding portions will be denoted by the same reference signs in all the drawings of the following embodiments.
1 One embodiment (Example of display device)
2 Modification Examples (Modification Examples of display device)
3 Application examples (Examples of electronic apparatus)

### 1 One Embodiment

### [Configuration of Display Device]

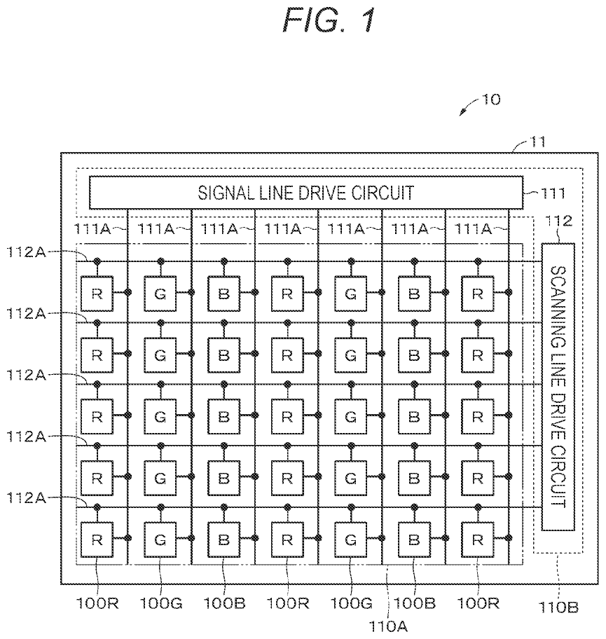

FIG. 1 is a schematic view illustrating an example of an overall configuration of a display device 10 according to one embodiment of the present disclosure. The display device 10 includes a display region 110A and a peripheral region 110B provided on a circumferential edge of the display region 110A. In the display region 110A, a plurality of subpixels 100R, 100G, and 100B is two-dimensionally arranged in a prescribed arrangement pattern such as a matrix shape.

The subpixel 100R can display a red color. The subpixel 100G can display a green color. The subpixel 100B can display a blue color. A red color is an example of a first primary color among three primary colors. A green color is an example of a second primary color among three primary colors. A blue color is an example of a third primary color among three primary colors. Note that in a case where the subpixels 100R, 100G, and 100B are collectively referred to without being particularly distinguished in the following description, they are referred to as subpixels 100. A combination of adjacent subpixels 100R, 100G, and 100B constitutes one pixel. FIG. 1 illustrates an example in which a combination of three subpixels 100R, 100G, and 100B aligned in a row direction (horizontal direction) constitutes one pixel, but the array of the subpixels 100R, 100G, and 100B is not limited thereto. The subpixels 100R, 100G, and 100B have, for example, a quadrangular shape such as a rectangular shape in planar view. In the present specification, a rectangular shape also contains a square shape. In the present specification, planar view means planar view when an object is viewed from a direction perpendicular to a display surface of the display device 10.

In the peripheral region 110B, a signal line drive circuit 111 and a scanning line drive circuit 112, which are drivers for displaying a video, are provided. The signal line drive circuit 111 supplies a signal voltage of a video signal corresponding to luminance information supplied from a signal supply source (not illustrated), to the subpixel 100 selected via a signal line 111A. The scanning line drive circuit 112 is constituted by a shift register or the like that sequentially shifts (transfers) a start pulse in synchronization with an input clock pulse. When video signals are written to the subpixels 100, the scanning line drive circuit 112 scans them row by row and sequentially supplies the scanned signals to corresponding scanning lines 112A.

The display device 10 is an example of a light emitting device. The display device 10 is a top emission type OLED display device. The display device 10 may be a microdisplay. The display device 10 may be included in a virtual reality (VR) device, a mixed reality (MR) device, an augmented reality (AR) device, an electronic view finder (EVF), a small projector, or the like.

In the following description, a surface on the top side (display surface side) of the display device 10 is referred to as a first surface, and a surface on the bottom side (opposite side to the display surface) of the display device 10 is referred to as a second surface, in each layer constituting the display device 10.

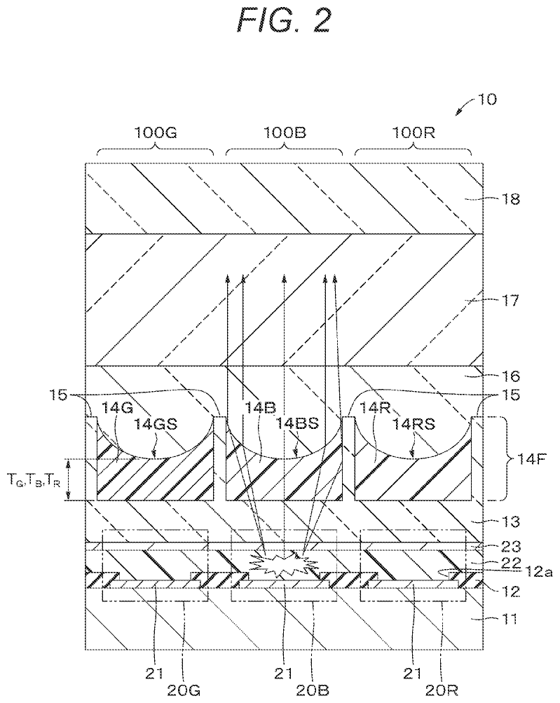

FIG. 2 is a cross-sectional view illustrating an example of a configuration of the display device 10 according to one embodiment. The display device 10 includes a drive substrate 11, a plurality of light emitting elements 20R, 20G, and 20B, an insulating layer 12, a protective layer 13, a color filter 14F, a wall part 15, a planarization layer 16, a sealing resin layer 17, and a counter substrate 18. Note that, in the following description, the light emitting elements 20R, 20G, and 20B will be referred to as light emitting elements 20 in a case where they are collectively referred to without being particularly distinguished.

### (Drive Substrate)

The drive substrate 11 is a so-called backplane and drives the plurality of light emitting elements 20. The drive substrate 11 is provided with a drive circuit that drives the plurality of light emitting elements 20, a power source circuit that supplies power to the plurality of light emitting elements 20, and the like (none of which is illustrated).

The substrate body of the drive substrate 11 may be constituted by, for example, a semiconductor which is easily formed into a transistor or the like or may be constituted by glass or resin each having low moisture and oxygen permeability. Specifically, the substrate body may be a semiconductor substrate, a glass substrate, a resin substrate, or the like. The semiconductor substrate contains, for example, amorphous silicon, polycrystalline silicon, monocrystalline silicon, or the like. The glass substrate contains, for example, high strain point glass, soda glass, borosilicate glass, forsterite, lead glass, quartz glass, or the like. The resin substrate contains, for example, at least one selected from a group including polymethyl methacrylate, polyvinyl alcohol, polyvinyl phenol, polyethersulfone, polyimide, polycarbonate, polyethylene terephthalate, polyethylene naphthalate, and the like.

### (Light Emitting Element)

The light emitting element 20R is contained in the subpixel 100R. The light emitting element 20G is contained in the subpixel 100G. The light emitting element 20B is contained in the subpixel 100B. The light emitting elements 20R, 20G, and 20B have the same configuration. The light emitting elements 20 are white OLED elements and can emit white light on a basis of control by a drive circuit or the like. The white OLED elements may be white micro-OLED (MOLED) elements. As a colorization method in the display device 10, a method using the white OLED elements and the color filter 14F is used.

The plurality of light emitting elements 20 is two-dimensionally arranged on the first surface of the drive substrate 11 in a prescribed arrangement pattern such as a matrix shape. The plurality of light emitting elements 20 sequentially includes a plurality of first electrodes 21, an OLED layer 22, and a second electrode 23 on the first surface of the drive substrate 11.

### (First Electrode)

The plurality of first electrodes 21 is two-dimensionally arranged on the first surface of the drive substrate 11 in an arrangement pattern similar to that of the plurality of subpixels 100. The first electrodes 21 are anodes. When a voltage is applied between the first electrodes 21 and the second electrode 23, holes are injected from the first electrodes 21 into the OLED layer 22. The first electrodes 21 are separately provided in the plurality of subpixels 100.

The first electrode 21 may be, for example, constituted by a metal layer or may be constituted by a metal layer and a transparent conductive oxide layer. In a case where the first electrode 21 is constituted by a metal layer and a transparent conductive oxide layer, the transparent conductive oxide layer is preferably provided on the OLED layer 22 side, from the viewpoint of allowing a layer having a high work function to adjoin the OLED layer 22.

The metal layer also has a function as a reflective layer that reflects light emitted from the OLED layer 22. The metal layer contains, for example, at least one metal element selected from a group including chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may contain the above-described at least one metal element as a constituent element of an alloy. A specific example of the alloy includes an aluminum alloy or a silver alloy. A specific example of the aluminum alloy includes, for example, AlNd or AlCu.

A base layer (not illustrated) may be provided adjacent to the second surface side of the metal layer. The base layer is for improving crystal orientation properties of the metal layer during formation of the metal layer. The base layer contains, for example, at least one metal element selected from a group including titanium (Ti) and tantalum (Ta). The base layer may contain the above-described at least one metal element as a constituent element of an alloy.

The transparent conductive oxide layer contains a transparent conductive oxide. The transparent conductive oxide contains, for example, at least one selected from a group including an indium-containing transparent conductive oxide (hereinafter, referred to as an “indium-based transparent conductive oxide”), a tin-containing transparent conductive oxide (hereinafter, referred to as a “tin-based transparent conductive oxide”), and a zinc-containing transparent conductive oxide (hereinafter, referred to as a “zinc-based transparent conductive oxide”).

The indium-based transparent conductive oxide contains, for example, indium tin oxide (ITO), indium zinc oxide (IZO), indium gallium oxide (IGO), or indium gallium zinc oxide (IGZO) fluorine-doped indium oxide (IFO). Among these transparent conductive oxides, indium tin oxide (ITO) is particularly preferable. This is because indium tin oxide (ITO) has a particularly low barrier for hole injection into the OLED layer 22 in terms of a work function, so that the drive voltage of the display device 10 can be particularly reduced. The tin-based transparent conductive oxide contains, for example, tin oxide, antimony-doped tin oxide (ATO), or fluorine-doped tin oxide (FTO). The zinc-based transparent conductive oxide contains, for example, zinc oxide, aluminum-doped zinc oxide (AZO), boron-doped zinc oxide, or gallium-doped zinc oxide (GZO).

### (OLED Layer)

The OLED layer 22 is provided between the plurality of first electrodes 21 and the second electrode 23. The OLED layer 22 is continuously provided over the plurality of subpixels 100 (that is, the plurality of blue subpixels 100B, the plurality of green subpixels 100G, and the plurality of red subpixels 100R) in the display region 110A and is shared by the plurality of subpixels 100 in the display region 110A.

The OLED layer 22 is an example of an organic layer that contains a light emitting layer. The OLED layer 22 can emit white light. The OLED layer 22 may be an OLED layer including a single-layer light emitting unit, an OLED layer including a two-layer light emitting unit (tandem structure), or an OLED layer having a structure other than these units. The OLED layer including a single-layer light emitting unit has, for example, a configuration in which a hole injection layer, a hole transport layer, a red light emitting layer, a light emitting separation layer, a blue light emitting layer, a green light emitting layer, an electron transport layer, and an electron injection layer are stacked in this order from the first electrodes 21 toward the second electrode 23. The OLED layer including a two-layer light emitting unit has, for example, a configuration in which a hole injection layer, a hole transport layer, a blue light emitting layer, an electron transport layer, a charge generation layer, a hole transport layer, a yellow light emitting layer, an electron transport layer, and an electron injection layer are stacked in this order from the first electrodes 21 toward the second electrode 23.

The hole injection layer is for enhancing hole injection efficiency into each light emitting layer and suppressing leakage. The hole transport layer is for enhancing hole transport efficiency to each light emitting layer. The electron injection layer is for enhancing electron injection efficiency into each light emitting layer. The electron transport layer is for enhancing electron transport efficiency to each light emitting layer. The light emitting separation layer is a layer for adjusting injection of carriers into each light emitting layer, and light emitting balance of each color is adjusted by injecting electrons or holes into each light emitting layer via the light emitting separation layer. The charge generation layer supplies electrons and holes to two light emitting layers between which the charge generation layer is sandwiched.

In response to application with an electric field to each of the red light emitting layer, the green light emitting layer, the blue light emitting layer, and the yellow light emitting layer, recombination occurs between holes injected from the first electrode 21 or the charge generation layer and electrons injected from the second electrode 23 or the charge generation layer, and red light, green light, blue light, and yellow light are emitted.

### (Second Electrode)

The second electrode 23 is a transparent electrode having transparency to visible light. In the present specification, visible light refers to light in a wavelength range of 360 nm or more and 830 nm. The second electrode 23 is provided to face the plurality of first electrodes 21. The second electrode 23 is continuously provided over the plurality of subpixels 100 in the display region 110A and is shared by the plurality of subpixels 100 in the display region 110A. The second electrode 23 is a cathode. In response to application with a voltage between the first electrodes 21 and the second electrode 23, electrons are injected from the second electrode 23 into the OLED layer 22.

The second electrode 23 is preferably constituted by a material having as high permeability as possible and a small work function in order to enhance light emitting efficiency. The second electrode 23 is constituted by, for example, at least one layer of a metal layer or a transparent conductive oxide layer. More specifically, the second electrode 23 is constituted by a single layer film of a metal layer or a transparent conductive oxide layer or by a stacked film of a metal layer and a transparent conductive oxide layer. In a case where the second electrode 23 is constituted by a stacked film, the metal layer may be provided on the OLED layer 22 side, or the transparent conductive oxide layer may be provided on the OLED layer 22 side, but from the viewpoint of allowing a layer having a low work function to adjoin the OLED layer 22, the metal layer is preferably provided on the OLED layer 22 side.

The metal layer contains, for example, at least one metal element selected from a group including magnesium (Mg), aluminum (Al), silver (Ag), calcium (Ca), and sodium (Na). The metal layer may contain the above-described at least one metal element as a constituent element of an alloy. A specific example of the alloy includes an MgAg alloy, an MgAl alloy, an AlLi alloy, or the like. The transparent conductive oxide layer contains a transparent conductive oxide. Examples of the transparent conductive oxide include materials similar to those of the above-described transparent conductive oxide of the first electrodes 21.

### (Insulating Layer)

The insulating layer 12 is provided in a portion between the separated first electrodes 21 on the first surface of the drive substrate 11. The insulating layer 12 insulates between the adjacent light emitting elements 20. More specifically, the insulating layer 12 insulates between the adjacent first electrodes 21. The insulating layer 12 has a plurality of openings 12a. Each of the plurality of openings 12a is provided corresponding to each subpixel 100. More specifically, each of the plurality of openings 12a is provided on the first surface (surface on the OLED layer 22 side) of each of the first electrodes 21. The first electrodes 21 and the OLED layer 22 are in contact with each other via the openings 12a.

The insulating layer 12 may be an organic insulating layer, an inorganic insulating layer, or a stacked body thereof. The organic insulating layer contains, for example, at least one selected from a group including a polyimide-based resin, an acrylic resin, a novolac-based resin, and the like. The inorganic insulating layer contains, for example, at least one selected from a group including silicon oxide (SiOₓ), silicon nitride (SiNₓ), silicon oxynitride (SiOₓN_{y}), and the like.

### (Protective Layer)

The protective layer 13 has transparency to visible light. The protective layer 13 is provided on the first surface of the second electrode 23 and covers the plurality of light emitting elements 20. The protective layer 13 shields the light emitting elements 20 from the outside air and suppresses moisture infiltration from the external environment into the light emitting elements 20. Further, in a case where the second electrode 23 is constituted by a metal layer, the protective layer 13 may have a function of suppressing oxidation of this metal layer.

The protective layer 13 contains, for example, an inorganic material or a polymer resin each having low hygroscopicity. The protective layer 13 may have a single layer structure or a multilayer structure. In a case where the thickness of the protective layer 13 is increased, a multilayer structure is preferable. This is for alleviating the internal stress in the protective layer 13. The inorganic material contains, for example, at least one selected from a group including silicon oxide (SiOₓ), silicon nitride (SiNₓ), silicon oxynitride (SiOₓN_{y}), titanium oxide (TiOₓ), aluminum oxide (AlOₓ), and the like. The polymer resin contains, for example, at least one selected from a group including a thermosetting resin, an ultraviolet curable resin, and the like.

### (Color Filter)

The color filter 14F is provided above the plurality of light emitting elements 20. More specifically, the color filter 14F is provided on the first surface of the protective layer 13. The color filter 14F is, for example, an on chip color filter (OCCF). The color filter 14F includes, for example, a plurality of red filter parts 14R, a plurality of green filter parts 14G, and a plurality of blue filter parts 14B. Note that in the following description, the red filter parts 14R, the green filter parts 14G, and the blue filter parts 14B will be referred to as filter parts 14 in a case where they are collectively referred to without being particularly distinguished. The red filter parts 14R, the green filter parts 14G, and the blue filter parts 14B may be provided at the same height with respect to the first surface of the drive substrate 11. The red filter parts 14R, the green filter parts 14G, and the blue filter parts 14B are examples of the filter parts 14 of a plurality of colors having colors different from each other. In the present embodiment, an example will be described in which the color filter 14F contains the filter parts 14 of three colors, but the filter parts 14 of a single color, the filter parts 14 of two colors, or the filter parts 14 of four or more colors may be contained in the color filter 14F.

The plurality of filter parts 14 is two-dimensionally arranged in the in-plane direction. In the present specification, the in-plane direction means an in-plane direction in the first surface of the drive substrate 11. Each of the filter parts 14 is provided above the light emitting element 20. The red filter part 14R and the light emitting element 20R constitute the subpixel 100R, the green filter part 14G and the light emitting element 20G constitute the subpixel 100G, and the blue filter part 14B and the light emitting element 20B constitute the subpixel 100B.

The red filter part 14R transmits red light out of the white light emitted from the light emitting element 20R but absorbs light other than the red light. The green filter part 14G transmits green light out of the white light emitted from the light emitting element 20G but absorbs light other than the green light. The blue filter part 14B transmits blue light out of the white light emitted from the light emitting element 20B but absorbs light other than the blue light.

The red filter part 14R has on the display surface side a concave surface 14RS bowed in a direction away from the display surface, and a refractive index n₂ of the planarization layer 16 and a refractive index n₃₁ of the red filter part 14R satisfy a relationship of n₂>n₃₁. This enables the display surface side of the red filter part 14R to have a function of a concave lens. The light emitted from the light emitting element 20R in the oblique direction with respect to the first surface of the drive substrate 11 and incident on the concave surface 14RS of the red filter part 14R is directed in the front direction by the light condensing function of the above-described concave lens.

The green filter part 14G has on the display surface side a concave surface 14GS bowed in a direction away from the display surface, and a refractive index n₂ of the planarization layer 16 and a refractive index n₃₂ of the green filter part 14G satisfy a relationship of n₂>n₃₂. This enables the display surface side of the green filter part 14G to have a function of a concave lens. The light emitted from the light emitting element 20G in the oblique direction with respect to the first surface of the drive substrate 11 and incident on the concave surface 14GS of the green filter part 14G is directed in the front direction by the light condensing function of the above-described concave lens.

The blue filter part 14B has on the display surface side a concave surface 14BS bowed in a direction away from the display surface, and a refractive index n₂ of the planarization layer 16 and a refractive index n₃₃ of the blue filter part 14B satisfy a relationship of n₂>n₃₃. This enables the display surface side of the blue filter part 14B to have a function of a concave lens. The light emitted from the light emitting element 20B in the oblique direction with respect to the first surface of the drive substrate 11 and incident on the concave surface 14BS of the blue filter part 14B is directed in the front direction by the light condensing function of the above-described concave lens. The concave surface 14RS is bowed in a direction away from the display surface. The refractive index n₂, the refractive index n₃₁, the refractive index n₃₂, and the refractive index n₃₃ represent refractive indexes for light having a wavelength of 550 nm.

The concave surfaces 14RS, 14GS, and 14BS are preferably concave curved surfaces. The concave curved surface is, for example, a meniscus shape with the concave surface facing the display surface side. The circumferential edges of the concave surfaces 14RS, 14GS, and 14BS are, for example, in contact with the side surface of the wall part 15.

A thickness T_{R} of the red filter part 14R, a thickness T_{G} of the green filter part 14G, and a thickness T_{B} of the blue filter part 14B are, for example, substantially the same. In the present specification, the thickness T_{R} of the red filter part 14R means the thickness at the bottom of the concave surface 14RS, the thickness T_{G} of the green filter part 14G means the thickness at the bottom of the concave surface 14GS, and the thickness T_{B} of the blue filter part 14B means the thickness at the bottom of the concave surface 14BS. The refractive indexes n3 of the red filter part 14R, the green filter part 14G, and the blue filter part 14B may be the same or different. The curvatures of the concave surfaces 14RS, 14GS, and 14BS may be the same.

The red filter part 14R is constituted by, for example, a red color resist. The green filter part 14G is constituted by, for example, a green color resist. The blue filter part 14B is constituted by, for example, a blue color resist.

### (Wall Part)

The wall part 15 is a so-called partition wall part and is provided on the first surface of the protective layer 13 and between the adjacent filter parts 14. The wall part 15 surrounds each of the filter parts 14 and separates the filter parts 14 from each other. The wall part 15 may be constituted by the same material as the protective layer 13 or may be constituted by a material different from the protective layer 13. The wall part 15 may have transparency to visible light, or the wall part 15 may have opacity to visible light. The side surface of the wall part 15 may be perpendicular to the first surface of the drive substrate 11.

The refractive index n₃₁ of the red filter part 14R and the refractive index n₄ of the wall part 15 preferably satisfy a relationship of n₃₁>n₄. This enables the light emitted from the light emitting element 20R in the oblique direction with respect to the first surface of the drive substrate 11 and incident on the wall part 15 via the red filter part 14R to be totally reflected. Therefore, the luminance of red light and the light extraction efficiency of red light in the front direction can be improved. The refractive index n₄ represents a refractive index for light having a wavelength of 550 nm.

The refractive index n₃₂ of the green filter part 14G and the refractive index n₄ of the wall part 15 preferably satisfy a relationship of n₃₂>n₄. This can improve the luminance of green light and the light extraction efficiency of green light in the front direction.

The refractive index n₃₃ of the blue filter part 14B and the refractive index n₄ of the wall part preferably satisfy a relationship of n₃₃>n₄. This can improve the luminance of blue light and the light extraction efficiency of blue light in the front direction.

The wall part 15 contains, for example, an inorganic material or a polymer resin. Examples of the inorganic material and the polymer material include materials similar to those of the protective layer 13. The wall part 15 may be constituted by materials similar to those of the protective layer 13.

### (Planarization Layer)

The planarization layer 16 is provided on the first surface of the color filter 14F. The planarization layer 16 can planarize the unevenness of the first surface of the color filter 14F. The planarization layer 16 contains, for example, at least one selected from a group including a thermosetting resin, an ultraviolet curable resin, and the like.

### (Sealing Resin Layer)

The sealing resin layer 17 is provided between the planarization layer 16 and the counter substrate 18. The sealing resin layer 17 has a function as an adhesive layer for bonding the planarization layer 16 and the counter substrate 18. The sealing resin layer 17 contains, for example, at least one selected from a group including a thermosetting resin, an ultraviolet curable resin, and the like.

### (Counter Substrate)

The counter substrate 18 is provided on the first surface of the sealing resin layer 17 and faces the drive substrate 11. The counter substrate 18 and the sealing resin layer 17 seal the light emitting elements 20, the color filter 14F, and the like. The counter substrate 18 contains a material such as glass transparent to the light of each color emitted from the color filter 14F.

### [Method for Manufacturing Display Device]

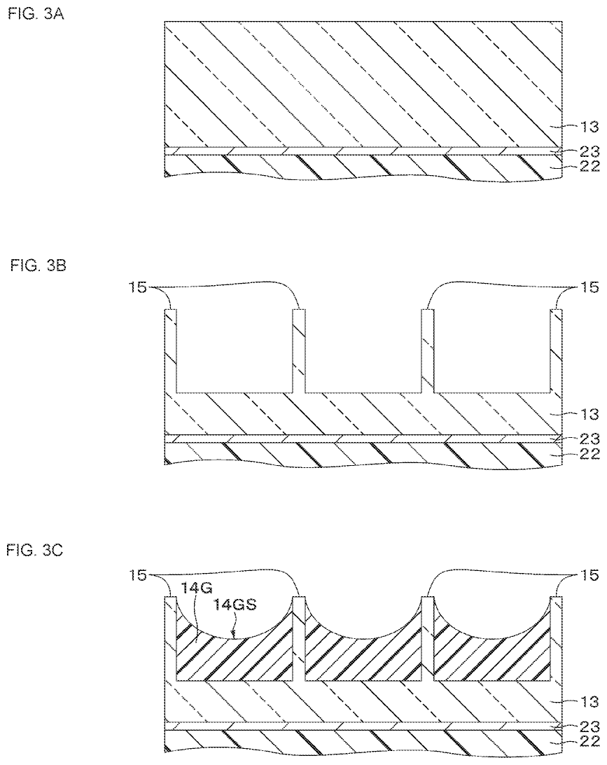

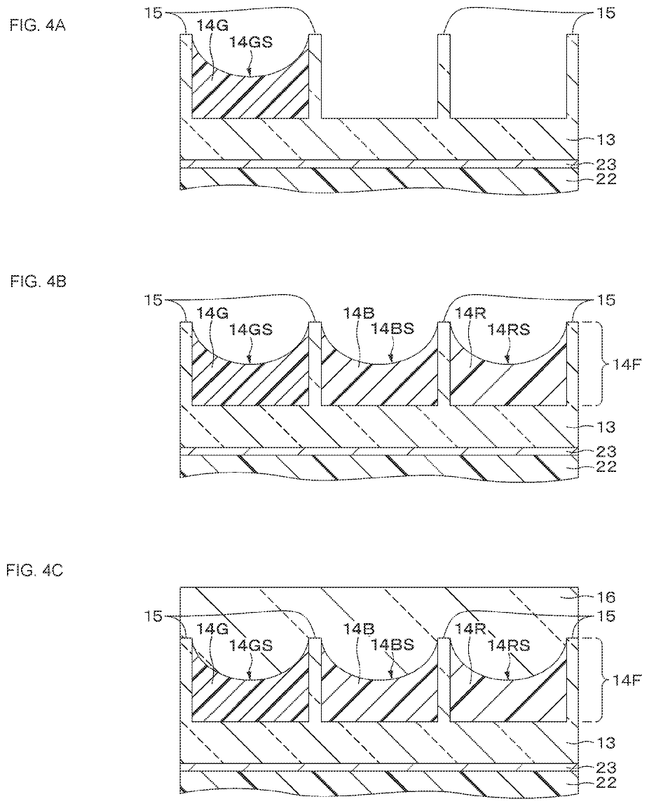

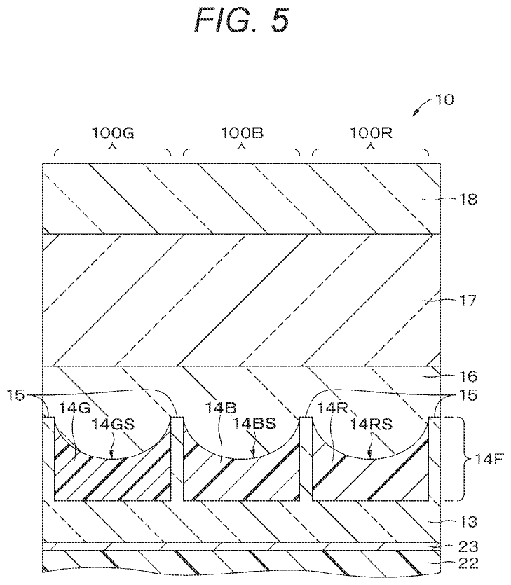

Hereinafter, an example of a method for manufacturing a display device 10 according to one embodiment will be described with reference to FIG. 3A to FIG. 3C, FIG. 4A to FIG. 4C, and FIG. 5.

First, a metal layer and a metal oxide layer are sequentially formed on the first surface of a drive substrate 11 by, for example, a sputtering method, and then the metal layer and the metal oxide layer are patterned using, for example, a photolithography technique and an etching technique. With this procedure, a plurality of first electrodes 21 is formed on the first surface of the drive substrate 11.

Next, an insulating layer 12 is formed on the first surface of the drive substrate 11 in such a manner as to cover the plurality of first electrodes 21 by, for example, a chemical vapor deposition (CVD) method. Next, an opening 12a is formed in a portion of the insulating layer 12 located on the first surface of each of the first electrodes 21 by, for example, a photolithography technique and a dry etching technique.

Next, a hole transport layer, a red light emitting layer, a light emitting separation layer, a blue light emitting layer, a green light emitting layer, an electron transport layer, and an electron injection layer are stacked in this order on the first surfaces of the plurality of first electrodes 21 and the first surface of the insulating layer 12 by, for example, a vapor deposition method, thereby forming an OLED layer 22.

Next, a second electrode 23 is formed on the first surface of the OLED layer 22 by, for example, a vapor deposition method or a sputtering method. With this procedure, a plurality of light emitting elements 20 is formed on the first surface of the drive substrate 11.

Next, as illustrated in FIG. 3A, a protective layer 13 is formed on the first surface of the second electrode 23 by, for example, a CVD method or a vapor deposition method. Next, the protective layer 13 is processed by, for example, a photolithography technique and a dry etching technique thereby to form a wall part 15 on the first surface of the protective layer 13, as illustrated in FIG. 3B.

Next, a green color resist is applied on the first surface of the protective layer 13, and each cell surrounded by the wall part 15 is filled with a green color resist thereby to form a meniscus (concave curved surface) in each cell, as illustrated in FIG. 3C. Next, the green color resist contained in the cell corresponding to a subpixel 100G is irradiated with light such as ultraviolet light to expose the green color resist. Next, the green color resist other than that in the exposed part is removed with a developer, so that a green filter part 14G is left only in each cell corresponding to the subpixel 100G, as illustrated in FIG. 4A.

Next, a red color resist is applied on the first surface of the protective layer 13, and each cell corresponding to a subpixel 100R and each cell corresponding to a subpixel 100B are filled with a red color resist to form a meniscus (concave curved surface) in each cell. Next, the red color resist contained in the cell corresponding to the subpixel 100R is irradiated with light such as ultraviolet light to expose the red color resist. Next, the red color resist other than that in the exposed part is removed with a developer, so that a red filter part 14R is left only in each cell corresponding to the subpixel 100R.

Next, a blue color resist is applied on the first surface of the protective layer 13, and each cell corresponding to the subpixel 100B is filled with a blue color resist to form a meniscus (concave curved surface) in each cell. Next, the blue color resist contained in the cell corresponding to the subpixel 100B is irradiated with light such as ultraviolet light to expose the blue color resist. Next, the blue color resist other than that in the exposed part is removed with a developer, so that a blue filter part 14B is left only in each cell corresponding to the subpixel 100B. With this procedure, as illustrated in FIG. 4B, a color filter 14F that contains a plurality of red filter parts 14R, a plurality of green filter parts 14G, and a plurality of blue filter parts 14B is obtained.

Next, a curable resin is applied on the first surface of the color filter 14F and cured. With this procedure, as illustrated in FIG. 4C, a planarization layer 16 is formed on the first surface of the color filter 14F. The curable resin contains, for example, at least one selected from a group including a thermosetting resin, an ultraviolet curable resin, and the like.

Next, the planarization layer 16 is covered with a sealing resin layer 17 using, for example, a one drop fill (ODF) method, and thereafter a counter substrate 18 is placed on the sealing resin layer 17. Next, for example, the sealing resin layer 17 is applied with heat or irradiated with ultraviolet light to cure the sealing resin layer 17, so that the planarization layer 16 and the counter substrate 18 are bonded with the sealing resin layer 17 interposed therebetween, as illustrated in FIG. 5. With this procedure, the display device 10 is sealed. With the above-described procedures, the display device 10 illustrated in FIG. 2 is obtained.

### [Operation and Effect]

In order to facilitate understanding of the operation and effect of the display device 10 according to one embodiment, the operation and effect will be described by comparing the configuration of a display device 410 according to a comparative example with the configuration of the display device 10 according to one embodiment.

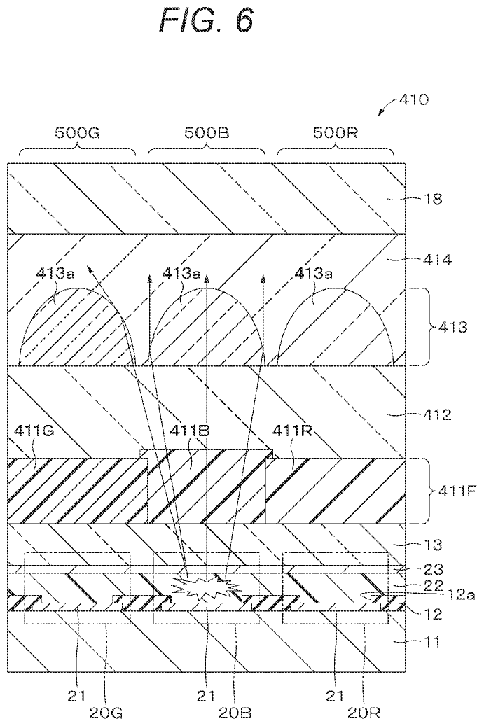

FIG. 6 is a cross-sectional view illustrating a configuration of a display device 410 according to a comparative example. The display device 410 includes a plurality of red subpixels 500R, a plurality of green subpixels 500G, and a plurality of blue subpixels 500B. Note that in the following description, the subpixels 500R, 500G, and 500B are collectively referred to subpixels 500 in a case where they are collectively referred to without being particularly distinguished. In the display device 410, a color filter 411, a planarization layer 412, a lens array 413, a sealing resin layer 414, and a counter substrate 18 are sequentially stacked on a protective layer 13.

The lens array 413 contains a plurality of lenses 413a. The lens 413a is an on chip lens (OCL) and has a convex curved surface protruding toward the display surface. The color filter 411 contains a plurality of red filter parts 411R, a plurality of green filter parts 411G, and a plurality of blue filter parts 411B.

Since the sealing resin layer 414 (refractive index nₐ) and the lens 413a (refractive index n_{b}) have a refractive index difference, light beams can be refracted at the interface between the lens 413a and the sealing resin layer 414. In a case where the refractive indexes nₐ and n_{b} satisfy a relationship of nₐ>n_{b}, it is possible to diffuse light at the interface between the lens 413a and the sealing resin layer 414 (that is, to deflect straight light in the oblique direction). On the other hand, in a case where the refractive indexes nₐ and n_{b} satisfy a relationship nₐ<n_{b}, it is possible to collect light at the interface between the lens 413a and the sealing resin layer 414 (that is, to direct the light emitted in the oblique direction toward the front direction). Therefore, luminance in the front direction can be improved.

However, the display device 410 having the above-described configuration has a problem in that, for example, the light transmitted through the blue filter part 411B of the subpixel 500B leaks to the lens 413a of the adjacent subpixel 500G, light cannot be effectively used, and luminance and light extraction efficiency in the front direction cannot be sufficiently improved.

The first factor for the occurrence of the above-described problem is that light easily leaks to the adjacent lens 413a because the light emitting position of the OLED layer 22 and the lens 413a are away from each other. In a case where the lens array 413 is formed on the color filter 411F, a plurality of layers such as the protective layer 13 (for example, a thickness of 1 μm), the color filter 411F (for example, a thickness of 2 μm), and the planarization layer 412 (for example, 0.5 μm) comes to be formed between the light emitting elements 20 and the lens array 413, and thus, the light emitting position of the OLED layer 22 and the lens array 413 inevitably become far from each other.

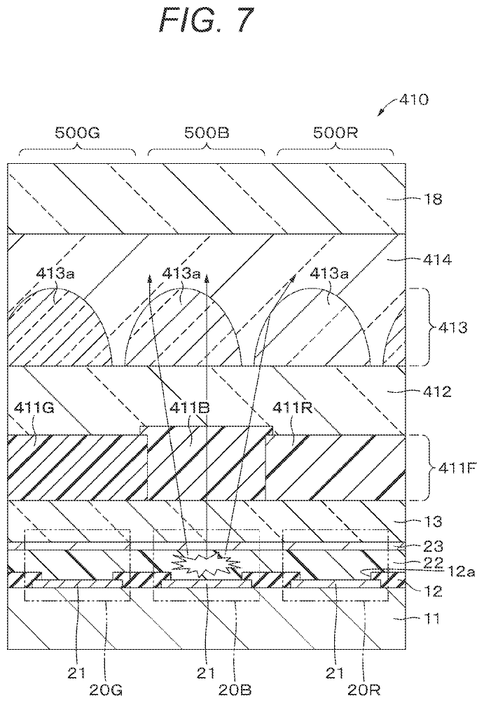

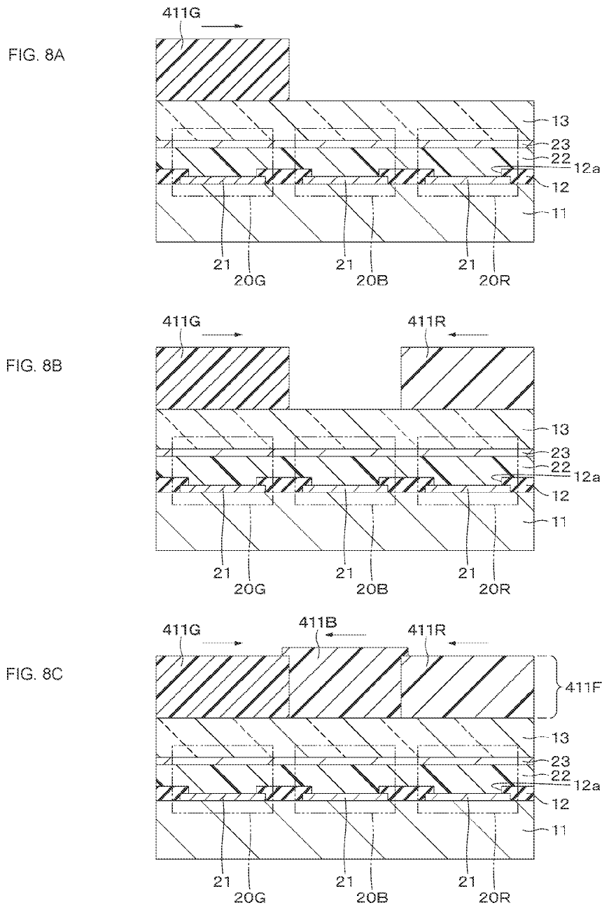

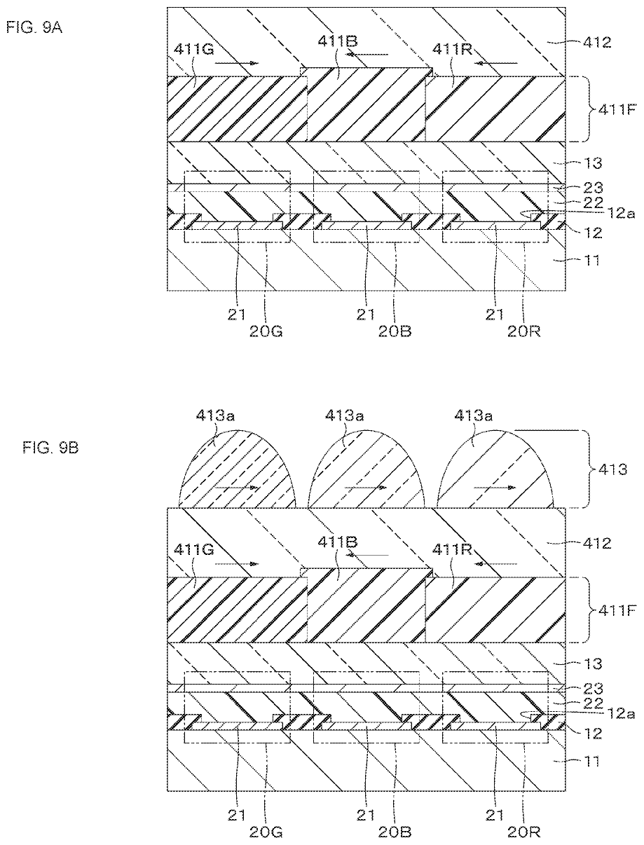

Further, the second factor for the occurrence of the above-described problem is that as illustrated in FIG. 7, light easily leaks to the adjacent lens 413a, due to positional displacement of each component attributable to a lithography process. FIG. 8A to FIG. 8C, FIG. 9A, and FIG. 9B are process diagrams for explaining a method for manufacturing the display device 410 according to a comparative example. Note that in FIG. 8A to FIG. 8C, FIG. 9A, and FIG. 9B, arrows indicate the directions of positional displacement of each component attributable to a lithography process.

As illustrated in FIG. 8A to FIG. 8C, FIG. 9A, and FIG. 9B, the green filter part 14G, the red filter part 14R, the blue filter part 14B, the planarization layer 412, and the lens array 413 are formed in this order on the first surface of the protective layer 13 by a photolithography process. In this case, since the color filter 14F and the lens array 413 are formed by separate lithography processes, the filter part 14 and the lens 413a are displaced in the in-plane direction. Therefore, the light transmitted through the filter part 14 of a predetermined subpixel 500 enters not only the lens 413a of the predetermined subpixel 500 but also the lens 413a of the subpixel 500 adjacent to the predetermined subpixel 500.

As described above, in the display device 10 according to one embodiment, the red filter part 14R, the green filter part 14G, and the blue filter part 14B respectively have the light emitting element 20R and, on the display surface side, the concave surfaces 14RS, 14GS, and 14BS. Further, the refractive index n₂ of the planarization layer 16, the refractive index n₃₁ of the red filter part 14R, the refractive index n₃₂ of the green filter part 14G, and the refractive index n₃₃ of the blue filter part 14B satisfy a relationship of n₂₁>n₃₁, n₃₂, n₃₃. This allows the red filter part 14R, the green filter part 14G, and the blue filter part 14B to have both a function as a general color filter and a function as a concave lens. Therefore, since the concave lenses (concave surfaces 14RS, 14RG, 14BS) can be brought close to the light emitting positions of the OLED layer 22, the light emitted from the light emitting element 20 of a predetermined subpixel 100 is less likely to leak to the concave lens (filter part 14) of the subpixel 100 adjacent to the predetermined subpixel 100, so that it is possible to effectively utilize more light than the display device 410 according to a comparative example.

Further, since the red filter part 14R, the green filter part 14G, and the blue filter part 14B themselves serve as lenses, occurrence of positional displacement between the filter part and the lens can be prevented. Thus, it is possible to prevent loss of light caused by positional displacement between the filter part and the lens.

Therefore, luminance and light extraction efficiency in the front direction can be improved as compared with the display device 410 according to Comparative Example 1.

In the display device 10 according to one embodiment, a plurality of cells constituted by the wall part 15 is formed on the first surface of the protective layer 13. This allows a color resist to be applied on the first surface of the protective layer 13 and a color resist to be charged into each cell surrounded by the wall part 15, so that a meniscus (concave curved surface) can be formed on the upper surface of the color resist charged in each cell. Taking advantage of this meniscus, the concave surfaces 14RS, 14GS, and 14BS can be formed on the display surface side of the red filter part 14R, the green filter part 14G, and the blue filter part 14B, respectively. Therefore, the red filter part 14R, the green filter part 14G, and the blue filter part 14B each having a lens function can be easily formed.

### 2 Modification Examples

### Modification Example 1

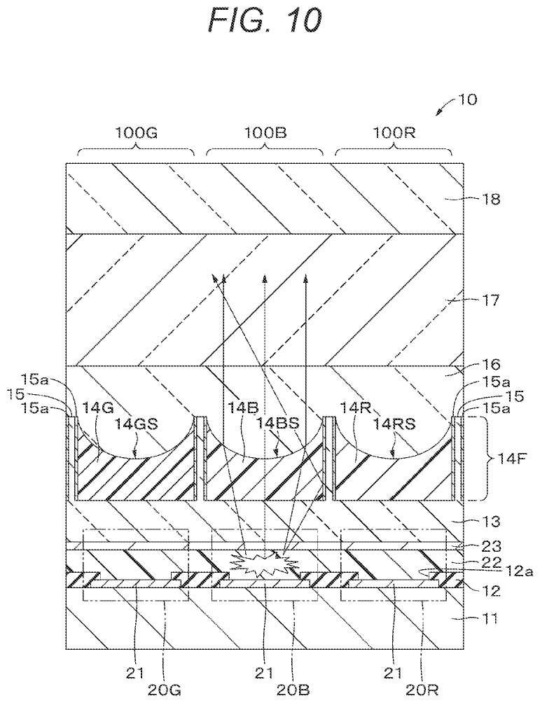

As illustrated in FIG. 10, the display device 10 may further include a reflection member 15a on both side surfaces of the wall part 15. The reflection members 15a contain, for example, metal. The metal contains, for example, at least one metal element selected from a group including silver (Ag) and aluminum (Al). The metal may contain the above-described at least one metal element as a constituent element of an alloy.

As described above, since the wall part 15 includes the reflection members 15a on both side surfaces, the light emitted from the light emitting element 20 in the oblique direction with respect to the first surface of the drive substrate 11 and incident on the wall part 15 via the filter part 14 can be reflected by the reflection member 15a. Therefore, luminance and light extraction efficiency in the front direction can be improved.

### Modification Example 2

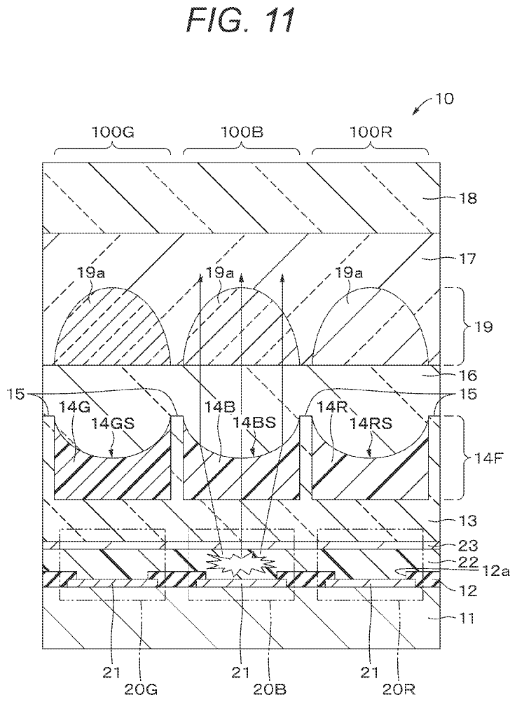

As illustrated in FIG. 11, the display device 10 may further include a lens array 19 on the first surface of the planarization layer 16. The lens array 19 contains a plurality of lenses 19a. The lens 19a condenses the light emitted upward from the filter part 14. The lens 19a has a convex curved surface protruding toward the display surface. The curved surface is, for example, a dome shape, a paraboloid shape, a hemispherical shape, a semi-ellipsoidal shape, or the like. The lens 19a is, for example, an on chip microlens (OCL). The plurality of lenses 19a is two-dimensionally arranged on the first surface of the planarization layer 16 in a prescribed arrangement pattern such as a matrix shape. The lens 19a is provided for each light emitting element 20. The lens 19a is provided above the filter part 14.

The refractive index n₂ of the planarization layer 16 and a refractive index n₅ of the lens 19a are preferably substantially the same, from the viewpoint of suppressing reflection at the interface between the planarization layer 16 and the lens 19a. In the present specification, substantially the same contains the same.

A refractive index n₁ of the sealing resin layer 17 and the refractive index n₅ of the lens 19a preferably satisfy a relationship of n₅>n₁. Since the refractive indexes n₁ and n₅ satisfy a relationship n₅>n₁, it is possible to collect light at the interface between the lens 19a and the sealing resin layer 17 (that is, to direct the light emitted in the oblique direction toward the front direction). Therefore, luminance in the front direction can be improved. The refractive index n₁ and the refractive index n₅ represent refractive indexes to light having a wavelength of 550 nm.

The lens 19a contains, for example, an inorganic material or a polymer resin each being transparent to visible light. The inorganic material contains, for example, silicon oxide (SiO₂). The polymer resin contains, for example, an ultraviolet curable resin.

As described above, since the display device 10 includes the lens array 19 on the first surface of the planarization layer 16, the light emitted from the light emitting elements 20R, 20G, and 20B are respectively condensed by the concave surfaces 14RS, 14GS, and 14BS of the respective color filter parts 14R, 14G, and 14B and thereafter further condensed by the lenses 19a. Therefore, luminance and light extraction efficiency in the front direction can be further improved.

### Modification Example 3

In the above-described one embodiment, an example has been described in which the red filter part 14R, the green filter part 14G, and the blue filter part 14B all have a concave surface on the display surface side, but the filter part of a specific color among the red filter part 14R, the green filter part 14G, and the blue filter part 14B may have a concave surface on the display surface side, and the remaining filter parts may have a flat surface on the display surface side. In this case, the filter part of a specific color among the red filter part 14R, the green filter part 14G, and the blue filter part 14B may be surrounded by the wall part 15, and the remaining filter parts may not be surrounded by the wall part 15.

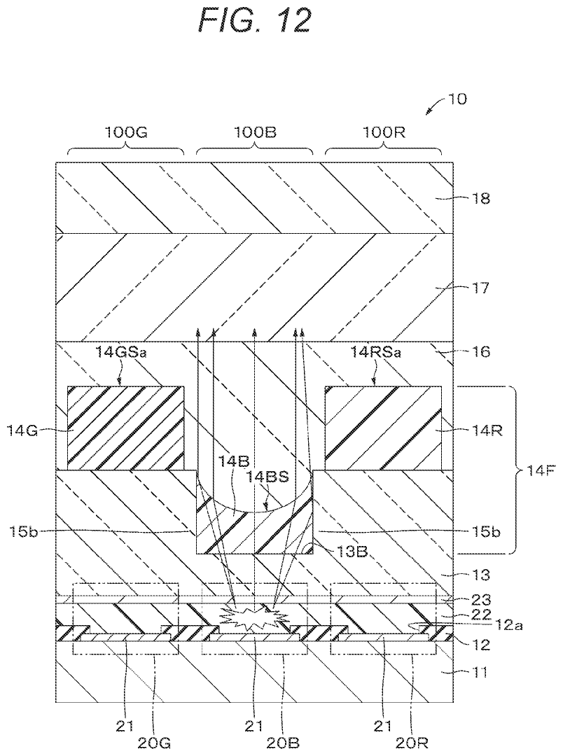

For example, as illustrated in FIG. 12, the blue filter part 14B among the red filter part 14R, the green filter part 14G, and the blue filter part 14B may have the concave surface 14BS on the display surface side, and the red filter part 14R and the green filter part 14G may have flat surfaces 14RSa and 14GSa on the display surface side, respectively. Only the blue filter part 14B among the red filter part 14R, the green filter part 14G, and the blue filter part 14B may be surrounded by a wall part 15b, and the red filter part 14R and the green filter part 14G may not be surrounded by the wall part 15b. The protective layer 13 may have a plurality of recesses 13B on the first surface, and the blue filter part 14B having the concave surface 14BS may be provided in each of the recesses 13B. The recess 13B may be provided above the light emitting element 20B. The wall part 15b surrounding the blue filter part 14B may be constituted by the side wall part of the recess 13B.

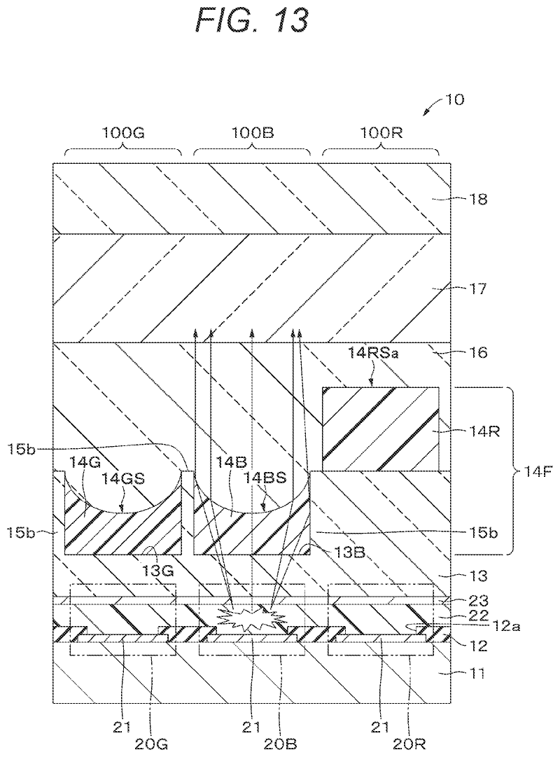

For example, as illustrated in FIG. 13, the green filter part 14G and the blue filter part 14B among the red filter part 14R, the green filter part 14G, and the blue filter part 14B may respectively have the concave surfaces 14GS and 14BS on the display surface side, and the red filter part 14R may have the flat surface 14RSa on the display surface side. The green filter part 14G and the blue filter part 14B among the red filter part 14R, the green filter part 14G, and the blue filter part 14B may be individually surrounded by the wall part 15b, and the red filter part 14R may not be surrounded by the wall part 15b. The protective layer 13 may have a plurality of recesses 13G and a plurality of recesses 13B on the first surface, the green filter part 14G having the concave surface 14GS may be provided in each of the recesses 13G, and the blue filter part 14B having the concave surface 14BS may be provided in each of the recesses 13B. The recess 13G may be provided above the light emitting element 20G, and the recess 13B may be provided above the light emitting element 20B. The wall part 15b surrounding the green filter part 14G may be constituted by the side wall part of the recess 13G. The wall part 15b surrounding the blue filter part 14B may be constituted by the side wall part of the recess 13B.

### Modification Example 4

In the above-described one embodiment, an example has been described in which the thicknesses of the red filter part 14R, the green filter part 14G, and the blue filter part 14B are the same, but the thicknesses of the red filter part 14R, the green filter part 14G, and the blue filter part 14B may be different. Here, the fact that the thicknesses of the red filter part 14R, the green filter part 14G, and the blue filter part 14B are different means that the thicknesses of the red filter part 14R, the green filter part 14G, and the blue filter part 14B are all different or that the thickness of the filter part of a specific color among the red filter part 14R, the green filter part 14G, and the blue filter part 14B is different from the thicknesses of the other filter parts. In a case where the thicknesses of the red filter part 14R, the green filter part 14G, and the blue filter part 14B are different, the color can be adjusted independently for each of the subpixel 100R, the subpixel 100G, and the subpixel 100B.

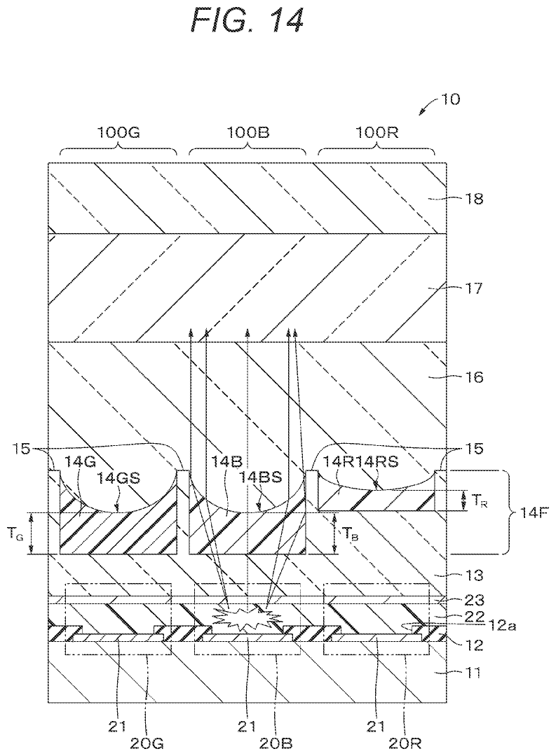

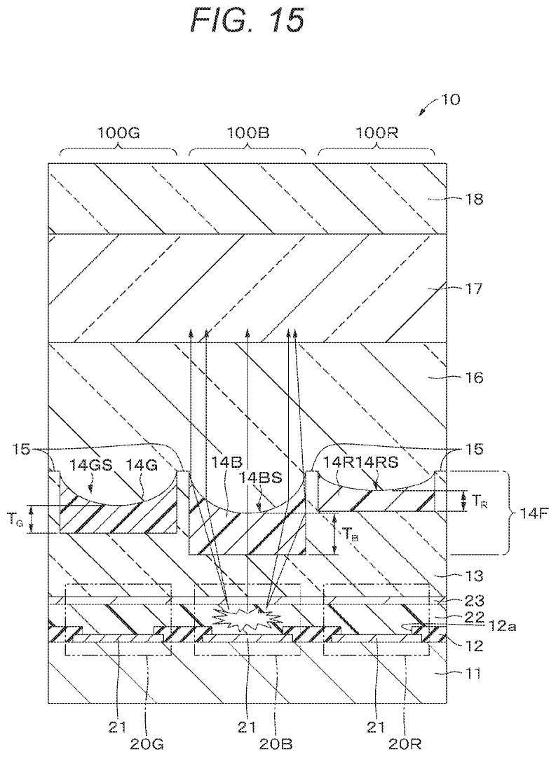

For example, as illustrated in FIG. 14, the thickness T_{B} of the blue filter part 14B among the red filter part 14R, the green filter part 14G, and the blue filter part 14B may be different from the thicknesses T_{R} and T_{G} of the red filter part 14R and the green filter part 14G. Alternatively, for example, as illustrated in FIG. 15, the thicknesses T_{R}, T_{G}, and T_{B} of the red filter part 14R, the green filter part 14G, and the blue filter part 14B may all be different. That is, the thickness of the filter part 14 may be different for each color of the filter part 14.

Due to a difference in thickness of the filter part 14 for each color of the filter part 14, the optical path length between the first electrode 21 and the filter part 14 may be different for each color of the subpixel 100, and a resonator structure may be formed between the first electrode 21 and the filter part 14. In a case where a resonator structure is constituted in this manner, color purity of the display device 10 can be improved.

Specifically, due to differences among the thickness T_{R} of the red filter part 14R, the thickness T_{G} of the green filter part 14G, and the thickness T_{B} of the blue filter part 14B, the optical path length between the first electrode 21 and the red filter part 14R, the optical path length among the first electrode 21 and the green filter part 14G, and the optical path length between the first electrode 21 and the blue filter part 14B are different.

The first electrode 21 and the red filter part 14R constitute a first resonator structure. The first resonator structure is set such that red light contained in the white light emitted by the OLED layer 22 can be resonated and emphasized. More specifically, for example, the optical path length between the first electrode 21 and the red filter part 14R in the red subpixel 100R is set to the spectrum peak wavelength of the red subpixel 100R.

The first electrode 21 and the green filter part 14G constitute a second resonator structure. The second resonator structure is set such that green light contained in the white light emitted by the OLED layer 22 can be resonated and emphasized. More specifically, for example, the optical path length between the first electrode 21 and the green filter part 14G in the green subpixel 100G is set to the spectrum peak wavelength of the green subpixel 100G.

The first electrode 21 and the blue filter part 14B constitute a third resonator structure. The third resonator structure is set such that blue light contained in the white light emitted by the OLED layer 22 can be resonated and emphasized. More specifically, for example, the optical path length between the first electrode 21 and the blue filter part 14B in the blue subpixel 100B is set to the spectrum peak wavelength of the blue subpixel 100B.

In a case where the display device 10 has the above-described resonator structure, it is preferable that a refractive index n₆ of the protective layer 13, a refractive index n₂, of the red filter part 14R, a refractive index n₂₂ of the green filter part 14G, and a refractive index n₂₃ of the blue filter part 14B satisfy a relationship of n₆>n₂₁, n₂₂, and n₂₃. In a case where the refractive indexes n₆, n₂₁, n₂₂, and n₂₃ satisfy the above-described relationship, the light emitted from the light emitting element 20 can be totally reflected at the interface between the protective layer 13 and the filter part 14R, 14G, or 14B of each color.

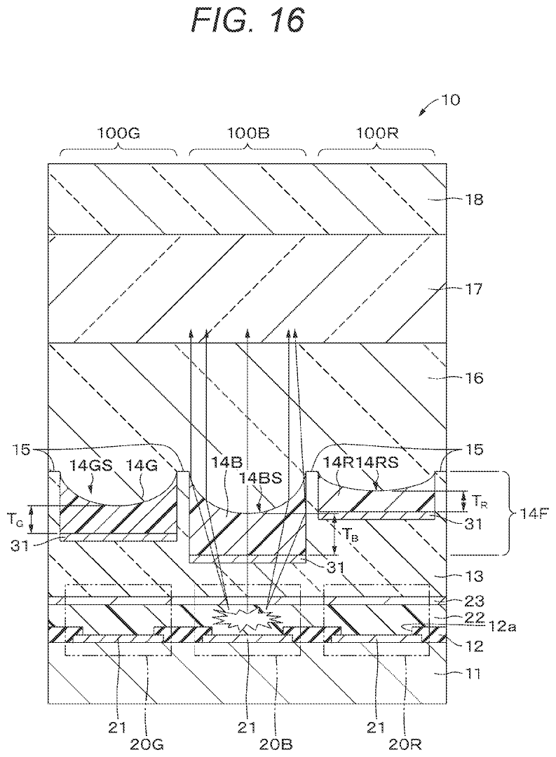

As illustrated in FIG. 16, a semi-transmissive reflective layer 31 may be provided on the bottom surface of each cell constituted by the wall part 15. That is, the semi-transmissive reflective layer 31 may be provided adjacent to the bottom surface (second surface) of each of the red filter part 14R, the green filter part 14G, and the blue filter part 14B. In this case, the semi-transmissive reflective layer 31 and the first electrode 21 included in the red subpixel 100R constitute a first resonator structure. The semi-transmissive reflective layer 31 and the first electrode 21 included in the green subpixel 100G constitute a second resonator structure. The semi-transmissive reflective layer 31 and the first electrode 21 included in the blue subpixel 100B constitute a third resonator structure.

The semi-transmissive reflective layer 31 transmits a part of the light generated in the OLED layer 22 and reflects the rest. The semi-transmissive reflective layer 31 is, for example, a metal layer. The metal layer contains, for example, at least one metal element selected from a group including magnesium (Mg), aluminum (Al), silver (Ag), calcium (Ca), gold (Au), copper (Cu), tin (Sn), zinc (Zn), sodium (Na), and the like. The metal layer may contain the above-described at least one metal element as a constituent element of an alloy. A specific example of the alloy includes an MgAg alloy, an MgAl alloy, an AlLi alloy, or the like.

The semi-transmissive reflective layer 31 may be a multilayer film in which a first metal layer and a second metal layer are stacked. The first metal layer of the first metal layer and the second metal layer may be provided on the OLED layer 22 side. The first metal layer contains, for example, at least one selected from a group including calcium (Ca), barium (Ba), lithium (Li), cesium (Cs), indium (In), magnesium (Mg), and silver (Ag). The first metal layer may contain the above-described at least one metal element as a constituent element of an alloy. The second metal layer contains, for example, at least one selected from a group including magnesium (Mg) and silver (Ag). The second metal layer may contain the above-described at least one metal element as a constituent element of an alloy.

### Modification Example 5

In the above-described one embodiment, an example has been described in which the curvatures of the concave surfaces 14RS, 14GS, and 14BS are the same, but the curvatures of the concave surfaces 14RS, 14GS, and 14BS may be different. Here, the fact that the curvatures of the concave surfaces 14RS, 14GS, and 14BS are different means that the curvatures of the concave surfaces 14RS, 14GS, and 14BS are all different for each color of the filter part 14 or that the curvature of the concave surface of the filter part 14 of a specific color among the concave surfaces 14RS, 14GS, and 14BS is different from the curvatures of the other filter parts.

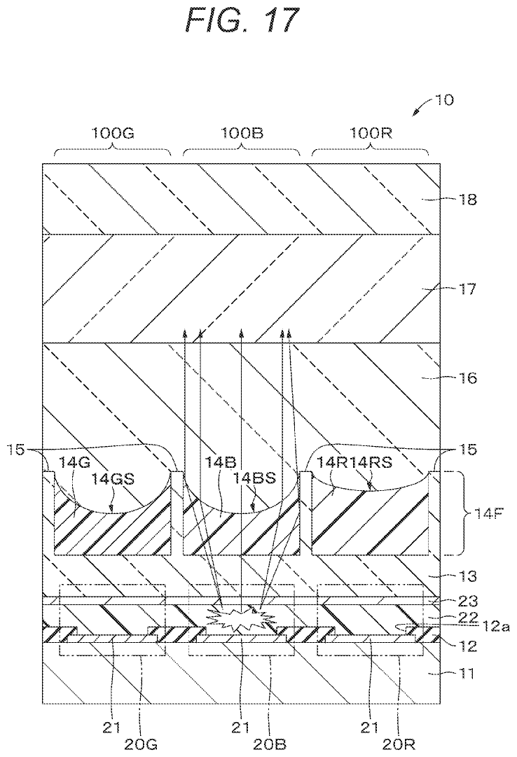

For example, as illustrated in FIG. 17, the curvature of the concave surface 14RS among the concave surfaces 14RS, 14GS, and 14BS may be different from the curvatures of the other concave surfaces 14GS and 14BS.

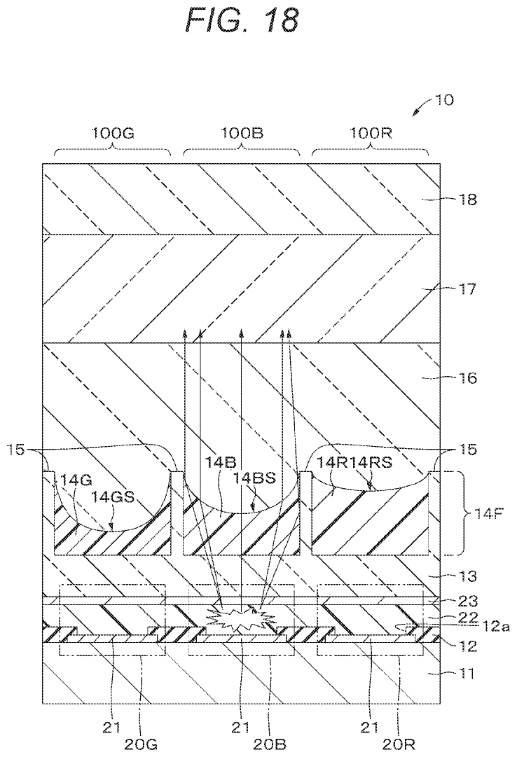

For example, as illustrated in FIG. 18, the curvatures of the concave surfaces 14RS, 14GS, and 14BS may all be different for each color of the filter part 14.

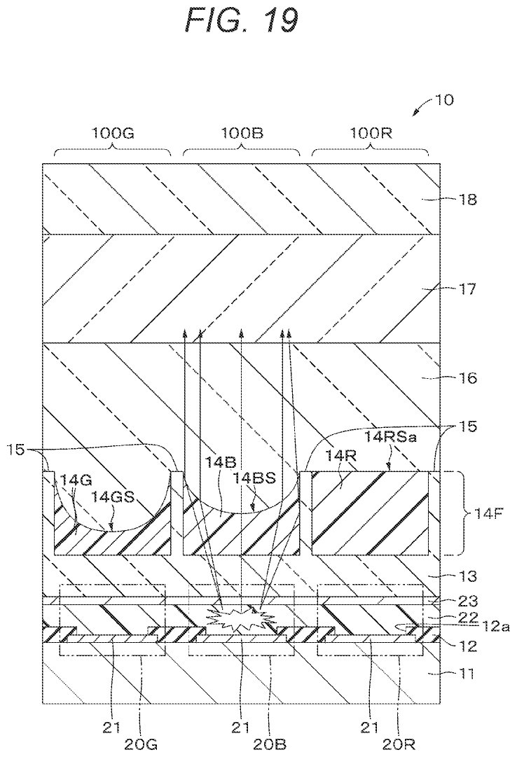

For example, as illustrated in FIG. 19, the curvatures of the surfaces (upper surfaces) on the display surface side of the green filter part 14G and the blue filter part 14B among the red filter part 14R, the green filter part 14G, and the blue filter part 14B may be greater than 0, whereas the curvature of the surface (upper surface) on the display surface side of the red filter part 14R among the red filter part 14R, the green filter part 14G, and the blue filter part 14B may be 0. That is, the green filter part 14G and the blue filter part 14B among the red filter part 14R, the green filter part 14G, and the blue filter part 14B may respectively have the concave surfaces 14GS and 14BS on the display surface side, whereas the red filter part 14R may have the flat surface 14RSa on the display surface side.

### Modification Example 6

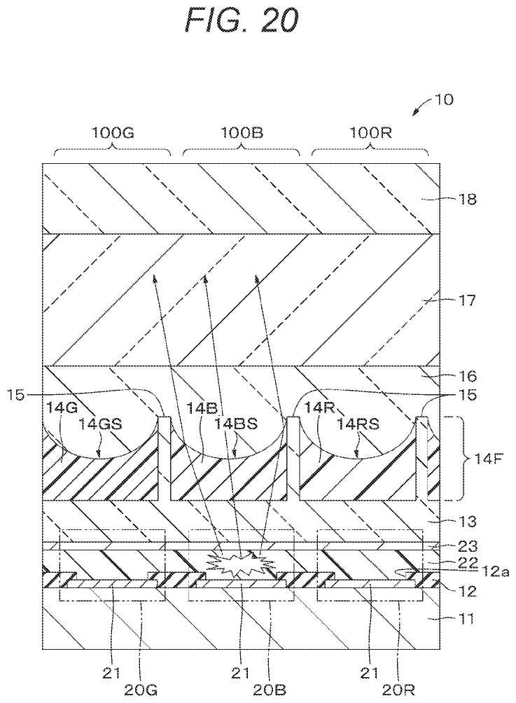

In the above-described one embodiment, an example has been described in which the bottom position of the filter part 14 (that is, the geometric center of the filter part 14) and the light emitting center position of the light emitting element 20 coincide in the in-plane direction in planar view, but the bottom position of the filter part 14 (that is, the geometric center of the filter part 14) and the light emitting center position of the light emitting element 20 may be shifted in the in-plane direction in planar view, as illustrated in FIG. 20. In a case where the bottom position of the filter part 14 and the light emitting center position of the light emitting element 20 are shifted in the in-plane direction as described above, the light emitted from the display surface of the display device 10 can be directed in the oblique direction with respect to the display surface. Therefore, luminance and light extraction efficiency in the oblique direction of the display surface can be increased.

### Modification Example 7

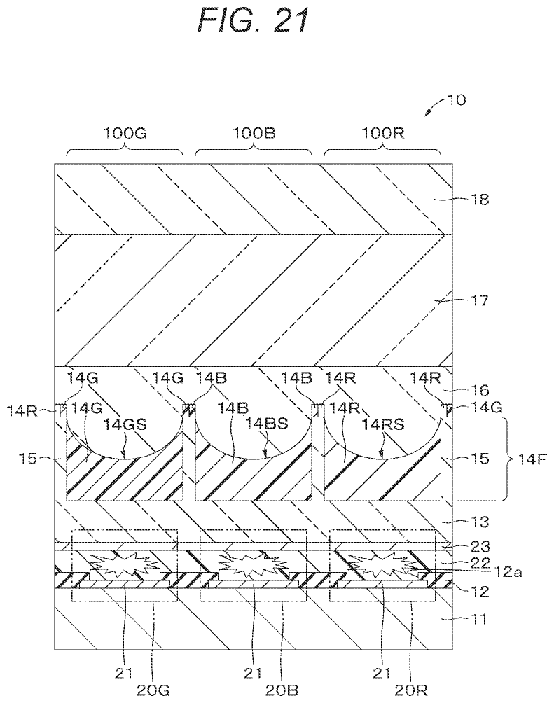

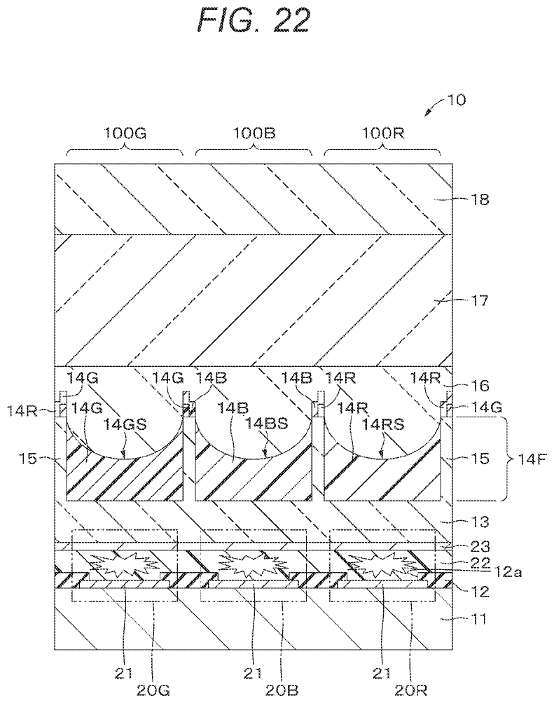

In the above-described one embodiment, an example has been described in which the circumferential edge of the concave surface 14RS, 14GS, or 14BS is in contact with the side surface of the wall part 15, but the circumferential edge of the concave surface 14RS, 14GS, or 14BS of the filter part 14R, 14G, or 14B of each color may ride on the wall part 15, as illustrated in FIG. 21. Alternatively, the circumferential edge of the concave surface of the filter part of a specific color among the red filter part 14R, the green filter part 14G, and the blue filter part 14B may ride on the wall part 15. In a case where the circumferential edges of both the adjacent filter parts 14 ride on the wall part 15, the circumferential edge portions riding on the wall part 15 may overlap each other, as illustrated in FIG. 22. In this case, the overlapping portion may constitute a light shielding part. In a case where the overlapping portion constitutes a light shielding part, the light emitted from the light emitting element 20 in the oblique direction with respect to the first surface of the drive substrate 11 can be shielded by the light shielding part, so that color mixing can be suppressed. In the present specification, the circumferential edge portion refers to a region having a predetermined width inward from the circumferential edge of the concave surface 14RS, 14GS, or 14BS.

### Modification Example 8

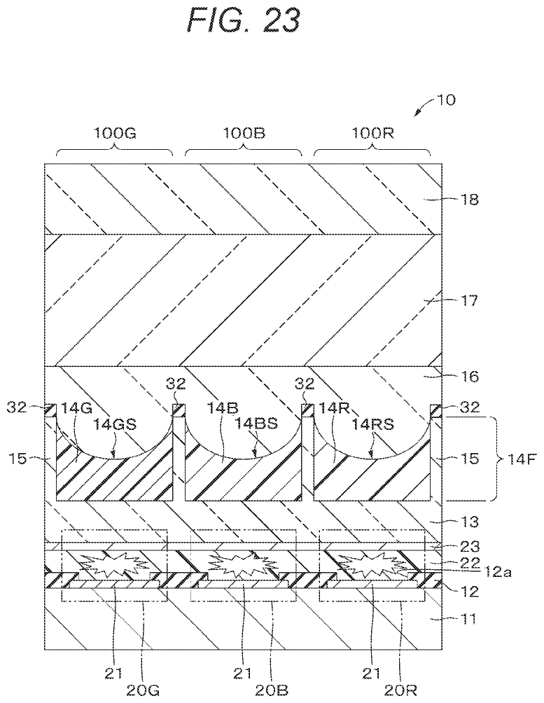

As illustrated in FIG. 23, the display device 10 may further include a light shielding part 32 on the wall part 15. The light shielding part 32 contains, for example, a light absorbing material. The light absorbing material contains, for example, at least one selected from a group including a black resin material and a black metal-containing material. The black resin material contains, for example, a black color resist and the like. The black metal-containing material contains, for example, titanium nitride (TiN) and the like. Since the light shielding part 32 is provided on the wall part 15 as described above, the light emitted from the light emitting element 20 in the oblique direction with respect to the first surface of the drive substrate 11 can be shielded by the light shielding part 32, so that color mixing can be suppressed.

### Modification Example 9

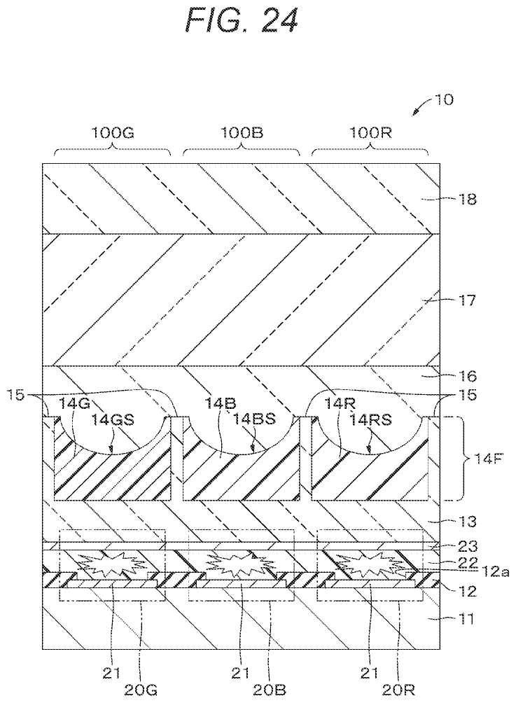

In the above-described one embodiment, an example has been described in which the circumferential edges of the concave surfaces 14RS, 14GS, and 14BS are in contact with the side surface of the wall part 15, but the circumferential edges of the concave surfaces 14RS, 14GS, and 14BS may be away from the side surface of the wall part 15, as illustrated in FIG. 24. Alternatively, the circumferential edge of the concave surface of the filter part 14 of a specific color among the concave surfaces 14RS, 14GS, and 14BS may be away from the side surface of the wall part 15. In a case where the circumferential edges of the concave surfaces 14RS, 14GS, and 14BS are away from the side surface of the wall part 15, a flat part may be provided between the circumferential edges of the concave surfaces 14RS, 14GS, and 14BS and the side surface of the wall part 15.

### Modification Example 10

In the above-described one embodiment, an example has been described in which the side surface of the wall part 15 is perpendicular to the first surface of the drive substrate 11, but the side surface of the wall part 15 may be inclined with respect to the first surface of the drive substrate 11. The inclined side surface may be a flat surface or may be a convex or concave curved surface. The curvatures of the concave surfaces 14RS, 14GS, and 14BS can be adjusted by adjusting the angle of the inclination of the side surface of the wall part 15. Further, luminance in the front direction can also be adjusted. The inclination angle of the side surface may be different for each of the subpixels 100R, 100G, and 100B.

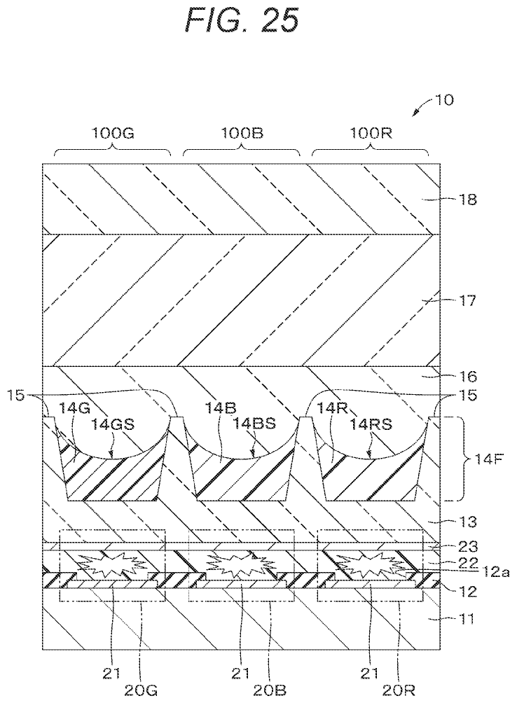

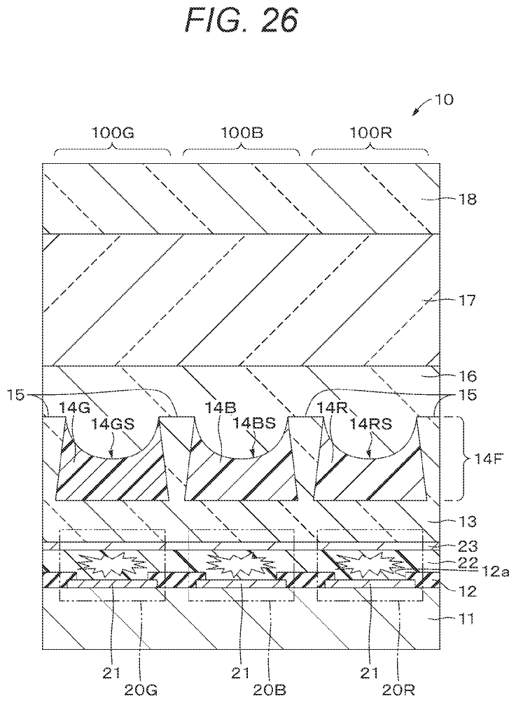

For example, as illustrated in FIG. 25, the cross-sectional shape of the wall part 15 may be a tapered shape in which the thickness of the wall part 15 decreases from the bottom toward the top of the wall part 15. Alternatively, as illustrated in FIG. 26, the cross-sectional shape of the wall part 15 may be an inversely tapered shape in which the thickness of the wall part 15 increases from the bottom toward the top of the wall part 15. Here, the cross-sectional shape of the wall part 15 means a shape of a two-dimensional surface that appears when the wall part 15 is cut in a direction perpendicular to the extending direction of the wall part 15.

### Modification Example 11

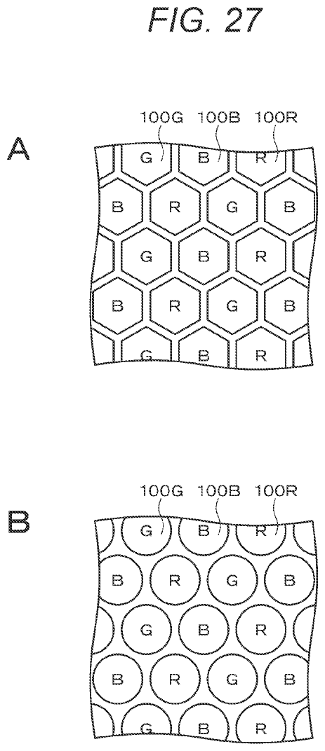

In the above-described one embodiment, an example has been described in which the subpixels 100R, 100G, and 100B (that is, the filter parts 14R, 14G, and 14B) have a quadrangular shape in planar view, but the subpixels 100R, 100G, and 100B (that is, the filter parts 14R, 14G, and 14B) may have a hexagonal shape (see FIG. 27A), a circular shape (see FIG. 27B), an elliptical shape, or the like in planar view.

### Modification Example 12

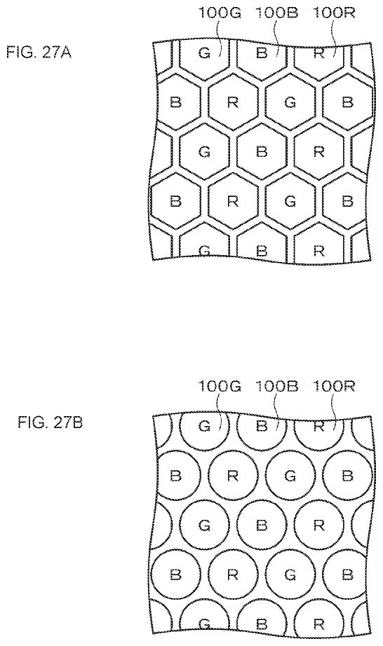

In the above-described one embodiment, an example has been described in which the subpixels 100R, 100G, and 100B (that is, the filter parts 14R, 14G, and 14B) have the same size in planar view, but the subpixels 100R, 100G, and 100B may be different in size in planar view, as illustrated in FIG. 28A. Here, the fact that the sizes of the subpixels 100R, 100G, and 100B are different means that the sizes of the subpixels 100R, 100G, and 100B are different for each color of the filter part 14 (that is, different for each color of the subpixel 100R, 100G, or 100B) or that the size of the subpixel of a specific color among the subpixels 100R, 100G, and 100B is different from the sizes of the other subpixels.

### Modification Example 13

In the above-described one embodiment, an example has been described in which the subpixels 100R, 100G, and 100B (that is, the filter parts 14R, 14G, and 14B) have the same shape, but the shapes of the subpixels 100R, 100G, and 100B may be different. Here, the fact that the shapes of the subpixels 100R, 100G, and 100B are different means that the shapes of the subpixels 100R, 100G, and 100B are different for each color of the filter part 14 (that is, different for each color of the subpixels 100R, 100G, or 100B) or that the shape of the subpixel of a specific color among the subpixels 100R, 100G, and 100B is different from the shapes of the other subpixels.

For example, as illustrated in FIG. 28B, the subpixels 100B and 100R may have a hexagonal shape, whereas the subpixel 100G may have a circular shape.

### Modification Example 14

In the above-described one embodiment, an example has been described in which one pixel is constituted by a combination of three subpixels 100R, 100G, and 100B, but one pixel may contain two or more subpixels 100 of the same color. In this case, among two or more subpixels having the same color, a specific subpixel may have a concave surface, and the remaining subpixel or subpixels may have a flat surface. This makes it possible to adjust the balance between the luminance in the front direction and the luminance in the oblique direction.

### Other Modification Examples

Although one embodiment of the present disclosure and modification examples thereof have been specifically described above, the present disclosure is not limited to the above-described one embodiment and modification examples thereof, and various modifications based on the technical idea of the present disclosure can be made.

For example, the configurations, methods, processes, shapes, materials, numerical values, and the like listed in the above-described one embodiment and modification examples thereof are merely examples, and configurations, methods, processes, shapes, materials, numerical values, and the like different therefrom may be used as necessary.

For example, the configurations, methods, processes, shapes, materials, numerical values, and the like of the above-described one embodiment and modification examples thereof can be combined with each other without departing from the gist of the present disclosure.

For example, the materials described as examples in the above-described one embodiment and modification examples thereof can be used singly or in combination of two or more unless otherwise specified.

Further, the present disclosure can also adopt the following configurations.
(1)
A display device including:
a substrate;
a plurality of light emitting elements provided on the substrate;
a color filter that is provided above a plurality of the light emitting elements and contains a plurality of filter parts; and
a wall part surrounding each of the filter parts, in which
the filter part has a concave surface on a display surface side.
(2)
The display device according to (1),
further including a planarization layer provided on the color filter, in which
a refractive index n₂ of the planarization layer and a refractive index n₃ of the filter part satisfy a relationship of n₂>n₃.
(3)
The display device according to (1) or (2), in which a refractive index n₃ of the filter part and a refractive index n₄ of the wall part satisfy a relationship of n₃>n₄.
(4)
The display device according to any one of (1) to (3), further including a lens array provided above the color filter.
(5)
The display device according to any one of (1) to (4), further including a reflection member provided on a side surface of the wall part.
(6)
The display device according to any one of (1) to (5), in which a circumferential edge of the concave surface is away from a side surface of the wall part.
(7)
The display device according to any one of (1) to (6), in which a side surface of the wall part is perpendicular to one main surface of the substrate or inclined with respect to one main surface of the substrate.
(8)
The display device according to any one of (1) to (7), in which a circumferential edge of the filter part is positioned on the wall part.
(9)
The display device according to (8), in which circumferential edge portions of the adjacent filter parts with the wall part interposed therebetween overlap each other on the wall part.
(10)
The display device according to any one of (1) to (9), further including a light shielding part provided on the wall part.
(11)
The display device according to any one of (1) to (10), in which a bottom position of the concave surface of the filter part is shifted from a light emitting center of the light emitting element.
(12)
The display device according to any one of (1) to (11), in which
a plurality of the filter parts is two-dimensionally arranged in an in-plane direction of the substrate, and
the wall part includes a partition wall part provided between the adjacent filter parts.
(13)
The display device according to any one of (1) to (11),
further including a protective layer provided between a plurality of the light emitting elements and the color filter, in which
the protective layer has a plurality of recesses on a surface on a side where the color filter is provided, and
the filter part having the concave surface is provided in the recess.
(14)
The display device according to any one of (1) to (13), in which
a plurality of the filter parts contains filter parts of a plurality of colors having colors different from each other, and
a curvature of the concave surface is different for each color of the filter part.
(15)
The display device according to any one of (1) to (13), in which
a plurality of the filter parts contains filter parts of a plurality of colors having colors different from each other, and
the filter part of a specific color among the filter parts of a plurality of colors has the concave surface.
(16)
The display device according to (15), in which the wall part surrounds the filter part of a specific color among the filter parts of a plurality of colors.
(17)
The display device according to any one of (1) to (13), in which
a plurality of the filter parts contains filter parts of a plurality of colors having colors different from each other, and
at least one of a shape or a size of the filter part in planar view differs depending on a color of the filter part.
(18)
The display device according to any one of (1) to (13), in which
a plurality of the filter parts contains filter parts of a plurality of colors having colors different from each other, and
a thickness of the filter part differs depending on a color of the filter part.
(19)
The display device according to (18), in which
the light emitting element includes a first electrode, an OLED layer, and a second electrode, and
due to a difference in thickness of the filter part for each color of the filter part, an optical path length between the first electrode and the filter part is different for each color of a subpixel, and a resonator structure is formed between the first electrode and the filter part.
(20)
The display device according to any one of (1) to (19), in which
a plurality of the filter parts contains:
a first filter part having a first primary color among three primary colors;
a first filter part having a second primary color among the three primary colors; and
a third filter part having a third primary color among the three primary colors.
(21)
The display device according to any one of (1) to (20), in which a shape of the filter part in planar view is a quadrangle, a hexagon, a circle, or an ellipse.
(22)
An electronic apparatus including the display device according to any one of (1) to (21).

### 3 Application Examples

### (Electronic Apparatus)

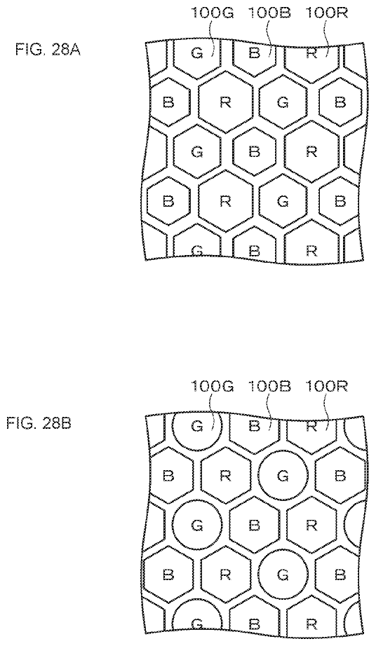

The display device 10 according to the above-described one embodiment and modification examples thereof can be used for various electronic apparatuses. The display device 10 is incorporated in various electronic apparatuses, for example, as a module as illustrated in FIG. 29. In particular, it is suitable for an electronic viewfinder of a video camera or a single-lens reflex camera, a head mounted display, and the like, which require high resolution and are used by magnifying in close proximity to the eyes. This module has a region 210 exposed without being covered with the counter substrate 18 and the like on one short side of the drive substrate 11, and an external connection terminal (not illustrated) is formed in this region 210 by extending wiring of the signal line drive circuit 111 and the scanning line drive circuit 112. A flexible printed circuit (FPC) 220 for inputting and outputting signals may be connected to this external connection terminal.

### Specific Example 1

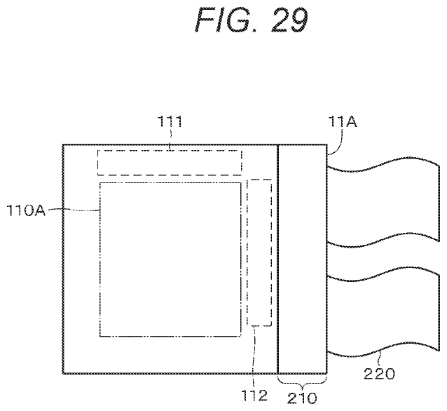

FIG. 30A and FIG. 30B illustrate an example of an external appearance of a digital still camera 310. The digital still camera 310 is of a lens interchangeable single-lens reflex type and has an interchangeable imaging lens unit (interchangeable lens) 312 substantially at the center of the front of a camera main body (camera body) 311 and a grip part 313 to be held by a photographer on the front left side.

A monitor 314 is provided in a position shifted to the left side from the center of the back of the camera main body 311. An electronic viewfinder (eyepiece window) 315 is provided above the monitor 314. By looking through the electronic viewfinder 315, the photographer can visually confirm an optical image of a subject guided from the photographing lens unit 312 and determine a picture composition. The electronic viewfinder 315 includes the display device 10.

### Specific Example 2

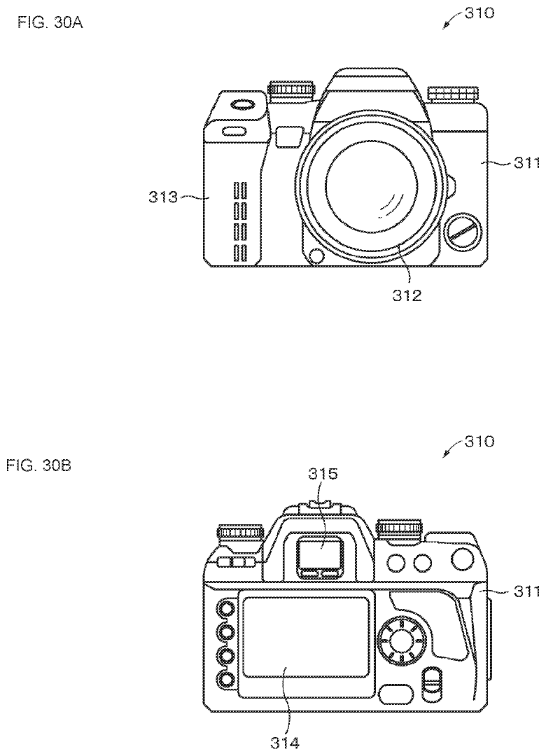

FIG. 31 illustrates an example of an external appearance of a head mounted display 320. The head mounted display 320 has, for example, an ear hooking part 322 to be worn on the head of a user, on both sides of a glasses-shaped display part 321. The display part 321 includes the display device 10.

### Specific Example 3

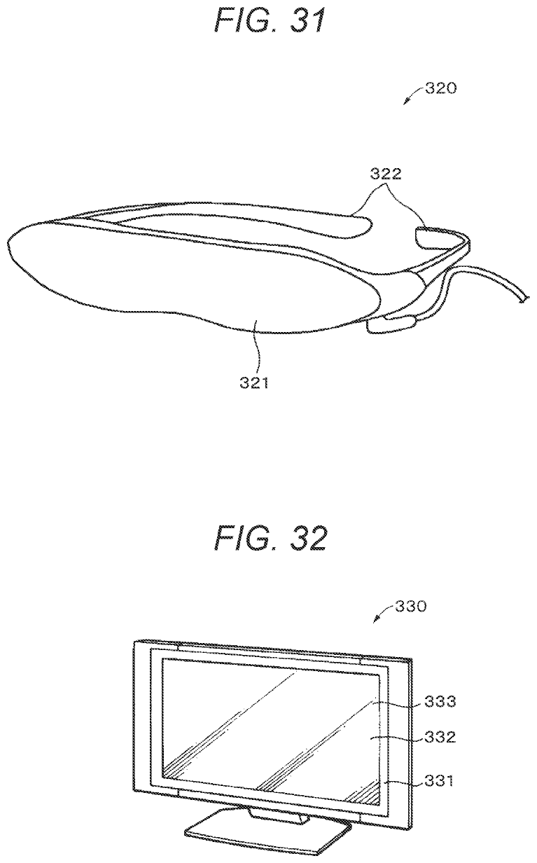

FIG. 32 illustrates an example of an external appearance of a television device 330. The television device 330 includes, for example, a video display screen part 331 that contains a front panel 332 and a filter glass 333, and the video display screen part 331 includes the display device 10.

### REFERENCE SIGNS LIST

10 Display device
11 Drive substrate
12 Insulating layer
12a Opening
13 Protective layer
14F Color filter
14R Red filter part
14G Green filter part
14B Blue filter part
14RS, 14GS, 14BS Concave surface
14RSa, 14GSa Flat surface
15, 15b Wall part
15a Reflection member
16 Planarization layer
17 Sealing resin layer
18 Counter substrate
19 Lens array
19a Lens
20 Light emitting element
21 First electrode
22 OLED layer
23 Second electrode
31 Semi-transmissive reflective layer
32 Light shielding part
100R, 100G, 100B Subpixel
110A Display region
110B Peripheral region
111 Signal line drive circuit
111A Signal line
112 Scanning line drive circuit
112A Scanning line
310 Digital still camera (electronic apparatus)
320 Head mounted display (electronic apparatus)
330 Television device (electronic apparatus)

1. A display device comprising:
a substrate;
a plurality of light emitting elements provided on the substrate;
a color filter that is provided above a plurality of the light emitting elements and contains a plurality of filter parts; and
a wall part surrounding the filter parts,
wherein the filter part has a concave surface on a display surface side.

2. The display device according to claim 1, further comprising a planarization layer provided on the color filter,
wherein a refractive index n₂ of the planarization layer and a refractive index n₃ of the filter part satisfy a relationship of n₂>n₃.

3. The display device according to claim 1, wherein a refractive index n₃ of the filter part and a refractive index n₄ of the wall part satisfy a relationship of n₃>n₄.

4. The display device according to claim 1, further comprising a lens array provided above the color filter.

5. The display device according to claim 1, further comprising a reflection member provided on a side surface of the wall part.

6. The display device according to claim 1, wherein a circumferential edge of the concave surface is away from a side surface of the wall part.

7. The display device according to claim 1, wherein a side surface of the wall part is perpendicular to one main surface of the substrate or inclined with respect to one main surface of the substrate.

8. The display device according to claim 1, wherein a circumferential edge of the filter part is positioned on the wall part.

9. The display device according to claim 8, wherein circumferential edge portions of the adjacent filter parts with the wall part interposed therebetween overlap each other on the wall part.

10. The display device according to claim 1, further comprising a light shielding part provided on the wall part.

11. The display device according to claim 1, wherein a bottom position of the concave surface of the filter part is shifted from a light emitting center of the light emitting element.

12. The display device according to claim 1, wherein
a plurality of the filter parts is two-dimensionally arranged in an in-plane direction of the substrate, and
the wall part includes a partition wall part provided between the adjacent filter parts.

13. The display device according to claim 1,
further comprising a protective layer provided between a plurality of the light emitting elements and the color filter, wherein
the protective layer has a plurality of recesses on a surface on a side where the color filter is provided, and
the filter part having the concave surface is provided in each of the recesses.

14. The display device according to claim 1, wherein
a plurality of the filter parts contains filter parts of a plurality of colors having colors different from each other, and
a curvature of the concave surface is different for each color of the filter part.

15. The display device according to claim 1, wherein
a plurality of the filter parts contains filter parts of a plurality of colors having colors different from each other, and
the filter part of a specific color among the filter parts of a plurality of colors has the concave surface.

16. The display device according to claim 15, wherein the wall part surrounds the filter part of a specific color among the filter parts of a plurality of colors.

17. The display device according to claim 1, wherein
a plurality of the filter parts contains filter parts of a plurality of colors having colors different from each other, and
at least one of a shape or a size of the filter part in planar view differs depending on a color of the filter part.

18. The display device according to claim 1, wherein
a plurality of the filter parts contains filter parts of a plurality of colors having colors different from each other, and
a thickness of the filter part differs depending on a color of the filter part.

19. The display device according to claim 18, wherein
the light emitting element includes a first electrode, an OLED layer, and a second electrode, and
due to a difference in thickness of the filter part for each color of the filter part, an optical path length between the first electrode and the filter part is different for each color of a subpixel, and a resonator structure is formed between the first electrode and the filter part.

20. An electronic apparatus comprising the display device according to claim 1.
